(19) United States
(12) Patent Application Publication
(10) Pub. No.: US 2013/0256639 A1
(43) Pub. Date: Oct. 3, 2013

(54) LIGHT EMITTING ELEMENT AND DISPLAY APPARATUS

(71) Applicant: SONY CORPORATION, Tokyo (JP)

(72) Inventors: Emiko Kambe, Kanagawa (JP); Yohei Ebihara, Kanagawa (JP); Masato Nakamura, Tokyo (JP); Kohji Hanawa, Kanagawa (JP); Jiro Yamada, Kanagawa (JP)

(73) Assignee: Sony Corporation, Tokyo (JP)

(21) Appl. No.: 13/848,176

(22) Filed: Mar. 21, 2013

(30) Foreign Application Priority Data
Mar. 28, 2012 (JP) 2012-072825
Mar. 29, 2012 (JP) 2012-076212

(51) Int. Cl. H01L 51/50; H01L 51/56

(52) U.S. Cl. CPC H01L 51/5096; H01L 51/56
USPC 257/40; 438/29

(57) ABSTRACT

There is provided a light emitting element including a first electrode, an organic layer having a light emitting layer, formed on the first electrode, a charge generation layer formed on the organic layer, a resistance layer formed on the charge generation layer, and a second electrode formed on the resistance layer. The first electrode reflects light emitted from the light emitting layer and the second electrode transmits the light emitted from the light emitting layer. The charge generation layer includes a layered structure of, sequentially in order from the organic layer, a mixing layer containing a chelate material, and an alkali earth metal element or an alkali metal element, and an acceptor layer containing an acceptor material.

### BACKGROUND

The present disclosure relates to a light emitting element, a manufacturing method of a light emitting element, a display apparatus, and a lighting apparatus, and specifically, relates to a light emitting element utilizing electroluminescence of an organic material and a manufacturing method thereof, and a display apparatus and a lighting apparatus using the light emitting element.

An organic electroluminescent element (so-called organic EL element) is a self-emitting element having a light emitting layer made of an organic compound between an anode and a cathode, and is attracting attention for realizing a display element large in area which is driven at low voltage. A display apparatus using such an organic electroluminescent element can realize the high functionality as an active matrix one in which a circuit having thin film transistors for driving the organic electroluminescent elements is formed on a substrate. Moreover, such an active matrix one does not restrict its screen size in principle, for an expected current can be injected and held for each pixel.

In manufacturing the active matrix display apparatus, the organic electroluminescent elements are formed on a substrate in which the thin film transistors are formed beforehand (so-called TFT substrate) in the state where they connect to the thin film transistors. Accordingly, a so-called top emission organic electroluminescent element, in which emitted light is taken from the upper electrode side opposite relative to the substrate, is advantageous in securing an aperture ratio of the pixel.

In the top emission organic electroluminescent element, light emitted from the element is taken from the upper electrode side by configuring the upper electrode of a transparent conductive film formed to have the polarity opposite to the lower electrode with respect to the lower electrode as an anode or a cathode. Moreover, in a white light element provided in consideration of a high-definition organic EL display that does not expect selective coating of a mask, a transparent electrode capable of attaining light emission over the entirety of the RGB region is important to be selected.

Herein, ITO and IZO generally used for the transparent conductive film have a work function up to approximately 5 eV, and are suitable for the anode but not suitable for the cathode. Therefore, in case, for example, of ITO used for a cathode material, it is proposed that an electron injection property is enhanced by layering, just beneath the cathode material, an electron injection layer which is obtained by mixing an alkali metal low in work function such as cesium and a material with an electron transport property (for example, see Japanese Patent Laid-Open No. 2006-140275).

Furthermore, an organic EL element has typically a structure in which a first electrode, an organic layer including a light emitting layer made of an organic light emitting material, and a second electrode are layered sequentially (for example, see International Publication No. WO 01/039554).

The serious problem in practical application of such an organic EL element may include short circuits between electrodes. Namely, according to the knowledge of the inventors, when there are particles (foreign matter) and/or projections on the first electrode, the organic layer which is formed on the first electrode and on which the second electrode is formed may not cover the first electrode completely, this resulting in short circuits between the first electrode and second electrode. For example, as illustrated in FIG. 29, when there is foreign matter 1203 on a first electrode 1202 formed on a substrate 1201, an organic layer 1204 may not completely cover the portion of this foreign matter 1203 significantly. In this case, forming a second electrode 1205 results in contact of the second electrode 1205 with the first electrode 1202 in the vicinity of the contact of the first electrode 1202 with the foreign matter 1203, this leading to short circuits.

In case of an active matrix organic EL display apparatus, such short circuits between the first electrode and second electrode as mentioned above result in missing pixels at the short circuits to aggravate display quality of the organic EL display apparatus. Moreover, in a passive matrix organic EL display apparatus, such short circuits result in missing lines at the short circuits also to aggravate display quality of the organic EL display apparatus. These cause a serious problem particularly in case of a large-sized organic EL display apparatus, this causing low tolerances for defects per unit area in such a large-sized organic EL display element.

Efforts to reduce short circuits between a first electrode and a second electrode as mentioned above have been made so far. For example, Japanese Patent Laid-Open No. 2001-035667 discloses a technology in which a high resistance layer is inserted between an anodic electrode and an organic layer in a bottom emission organic EL display apparatus. Moreover, Japanese Patent Laid-Open No. 2006-338916 discloses a technology in which an anodic electrode includes two layers and the layer that is included in the anodic electrode near an organic layer is made high in resistance in a top emission organic EL display apparatus. Moreover, Japanese Patent Laid-Open No. 2005-209647 discloses a technology in which a cathodic electrode includes two layers and the layer that is included in an anodic electrode near an organic layer is made high in resistance in a bottom emission organic EL display apparatus. Furthermore, Japanese Patent Laid-Open No. 2010-056075 discloses a technology in which a high resistance layer is inserted between an organic layer and a second electrode in a top emission organic EL display apparatus.

### SUMMARY

Even the technology proposed in Japanese Patent Laid-Open No. 2006-140275 mentioned above, however, does not solve an electron injection barrier between the transparent electrode and organic layer, and moreover, results in a lifetime decrease caused by sputtering damage on inorganic oxide films and/or short circuits between the anode and cathode based on high conductivity.

It is desirable to provide a light emitting element and a display apparatus high in efficiency and long in lifetime which have high reliability and can handle a wide view angle and high definition.

On the other hand, in the case of preventing short circuits between the first electrode and second electrode using the technologies disclosed in International Publication No. WO 01/039554, Japanese Patent Laid-Open No. 2001-035667, Japanese Patent Laid-Open No. 2006-338916, and Japanese Patent Laid-Open No. 2005-209647, there may be a disadvantage regarding view angle characteristics on chromaticity and luminance of the organic EL display apparatus. Namely, organic EL elements are typically affected by interference and resonance caused by structures of the organic layer and electrodes when light generated from the light emitting layer passes outside. These influences of interference and resonance cause view angle dependency on the chromaticity and luminance. Namely, there is sometimes large variation of the spectrum of light and/or a significant decrease in the intensity of light from the organic EL display apparatus as the view angle becomes wider. Hence, it is desirable to suppress the influences of interference as low as possible. In order to minimize the influences of interference, the pitch of the interference can be made narrow by separating the first electrode from the second electrode. The technologies in International Publication No. WO 01/039554, Japanese Patent Laid-Open No. 2001-035667, Japanese Patent Laid-Open No. 2006-338916, and Japanese Patent Laid-Open No. 2005-209647, however, forcibly define the thicknesses and resistivities of the individual layers in order to prevent short circuits between the first electrode and second electrode, and therefore, the first electrode is difficult to be separated arbitrarily from the second electrode. Moreover, thickening the high resistance layer causes high resistance and a significant elevation of drive voltage of the organic EL element, and thus, deteriorates characteristics of the element.

It is desirable to provide a light emitting element and a manufacturing method thereof which do not cause short circuits between the first electrode and second electrode and is excellent in view angle characteristics and low in driving voltage even in case of the presence of particles (foreign matter) and/or projections on the first electrode

It is also desirable to provide a display apparatus excellent in view angle characteristics and high in image quality which apparatus uses the above-mentioned excellent light emitting element.

It is further also desirable to provide a lighting apparatus less in angle dependency and excellent in light distribution which apparatus uses the above-mentioned excellent light emitting element.

According to an embodiment of the present disclosure, there is provided a light emitting element including a first electrode, an organic layer having a light emitting layer, formed on the first electrode, a charge generation layer formed on the organic layer, a resistance layer formed on the charge generation layer, and a second electrode formed on the resistance layer. The first electrode reflects light emitted from the light emitting layer and the second electrode transmits the light emitted from the light emitting layer. The charge generation layer includes a layered structure of, sequentially in order from the organic layer, a mixing layer containing a chelate material, and an alkali earth metal element or an alkali metal element, and an acceptor layer containing an acceptor material.

Moreover, according to the embodiment of the present disclosure, there is provided a display apparatus including the above-mentioned light emitting element.

According to an embodiment of the present disclosure, there is provided a light emitting element including a first electrode, an organic layer including a light emitting layer of an organic light emitting material, on the first electrode, a first resistance layer on the organic layer, a second resistance layer including a material lower in electric resistivity than a material included in the first resistance layer, on the first resistance layer, and a second electrode on the second resistance layer. One of the first electrode and the second electrode reflects light from the light emitting layer and the other of the first electrode and the second electrode transmits the light from the light emitting layer. A total thickness of the first resistance layer and the second resistance layer is 1 μm or more.

According to an embodiment of the present disclosure, there is provided a method for manufacturing a light emitting element, the method including forming a first electrode on a substrate, forming an organic layer including a light emitting layer of an organic light emitting material, on the first electrode, sequentially forming, on the organic layer, a first resistance layer and a second resistance layer of a material lower in electric resistivity than a material included in the first resistance layer, and forming a second electrode on the second resistance layer. One of the first electrode and the second electrode reflects light from the light emitting layer and the other of the first electrode and the second electrode transmits the light from the light emitting layer. A total thickness of the first resistance layer and the second resistance layer is 1 μm or more.

According to an embodiment of the present disclosure, there is provided a display apparatus including at least one light emitting element including a first electrode, an organic layer including a light emitting layer of an organic light emitting material, on the first electrode, a first resistance layer on the organic layer, a second resistance layer of a material lower in electric resistivity than a material included in the first resistance layer, on the first resistance layer, and a second electrode on the second resistance layer. One of the first electrode and the second electrode reflects light from the light emitting layer and the other of the first electrode and the second electrode transmits the light from the light emitting layer. A total thickness of the first resistance layer and the second resistance layer is 1 μm or more.

According to an embodiment of the present disclosure, there is provided a lighting apparatus including at least one light emitting element including a first electrode, an organic layer including a light emitting layer of an organic light emitting material, on the first electrode, a first resistance layer on the organic layer, a second resistance layer of a material lower in electric resistivity than a material included in the first resistance layer, on the first resistance layer, and a second electrode on the second resistance layer. One of the first electrode and the second electrode reflects light from the light emitting layer and the other of the first electrode and the second electrode transmits the light from the light emitting layer. A total thickness of the first resistance layer and the second resistance layer is 1 μm or more.

In the present disclosure, preferably, the electric resistivity of a material included in the first resistance layer is 1×10⁶ Ω·m or more and 1×10¹⁰ Ω·m and the thickness of the first resistance layer is 0.1 μm or more and 1 μm or less, whereas they are not limited to those. Moreover, preferably, the electric resistivity of a material included in the second resistance layer is 1×10⁰ Ω·m or more and 1×10⁵ Ω·m and the thickness of the second resistance layer is 0.5 μm or more, whereas they are not limited to those. Materials included in the first resistance layer and second resistance layer are selected as wanted, whereas they are typically made of oxide semiconductor. The oxide semiconductor used can include a mixture of one or two or more kinds of known ones.

This light emitting element may be configured in a top emission manner, and may be configured in a bottom emission manner. The top emission light emitting element includes the first electrode formed on the substrate which electrode reflects light from the light emitting layer and the first resistance layer, second resistance layer and second electrode which pass the light from the light emitting layer. This substrate may be opaque or transparent and selected as wanted. The bottom emission type light emitting element includes the first electrode formed on the substrate, first resistance layer, second resistance layer, and further, the substrate which pass light from the light emitting layer and the second electrode reflecting the light from the light emitting layer.

The display apparatus and lighting apparatus according to the embodiment of the present disclosure may have known configurations, and may be configured according to usage, functions and the like thereof. As a typical example, the display apparatus includes a drive substrate in which active elements (thin film transistors and the like) for supplying display signals corresponding to individual display pixels to light emitting elements are provided, and a sealing substrate disposed opposite to this drive substrate. The light emitting elements are arranged between the drive substrate and sealing substrate. This display apparatus may be any of a white display apparatus, a monochrome display apparatus, a color display apparatus and the like. The color display apparatus includes typically a color filter which passes light radiating from the side of an electrode from which the light from the light emitting element radiates out of electrodes of the drive substrate and sealing substrate and is provided on the substrate on this side.

According to the embodiment of the present disclosure mentioned above, the first resistance layer and the second resistance layer of a material lower in electric resistivity than a material included in this first resistance layer are formed on the organic layer. The total thickness of these first resistance layer and second resistance layer is large enough, being 1 μm or more. Therefore, even when there are particles (foreign matter) and/or projections on the first electrode and the organic layer formed thereon does not cover the first electrode completely, the first resistance layer and second resistance layer sufficiently cover these particles (foreign matter) and/or projections. Therefore, short circuits between the first electrode and second electrode can be prevented. Moreover, when the thickness of the first resistance layer is not so large and the thickness of the second resistance layer of a material lower in electric resistivity than a material including the first resistance layer is large, the total resistivity of the first resistance layer and second resistance layer can be suppressed low. Therefore, drive voltage of the light emitting element can be suppressed low. Moreover, since the distance between the first electrode and second electrode can be made large sufficiently, the influences of interference of light from the light emitting layer can be almost ignored. Hence, view angle dependency of the light emitting element can be minimized sufficiently, and excellent view angle characteristics can be attained.

As described above, it is desirable to provide a light emitting element and a display apparatus high in efficiency and long in lifetime which have high reliability and can handle a wide view angle and high definition.

Furthermore, even when there are particles (foreign matter) and/or projections on the first electrode, a light emitting element can be realized in which short circuits between the first electrode and second electrode do not arise and which is excellent in view angle characteristics and low in drive voltage. Using this excellent light emitting element, a display apparatus excellent in view angle characteristics and high in image quality and a lighting apparatus less in angle dependency and excellent in light distribution characteristics can be realized.

### BRIEF DESCRIPTION OF THE DRAWINGS

FIG. 1 is a schematic cross-sectional view of an organic electroluminescent element according to an embodiment of the present disclosure;

FIGS. 2(A) and 2(B) are diagrams illustrating one example of a circuit configuration of a display apparatus according to the embodiment;

FIG. 3 is a diagram illustrating one example of a cross-sectional configuration of the main part in the display apparatus according to the embodiment;

FIG. 4 is a configuration diagram illustrating a display apparatus in a module shape with a sealed structure to which the organic electroluminescent element according to the embodiment is applied;

FIG. 5 is a perspective view illustrating a television device to which the display apparatus according to the embodiment is applied;

FIG. 6 is a diagram illustrating a digital camera to which the display apparatus according to the embodiment is applied, and FIG. 6(A) is a perspective view as seen from a front side and FIG. 6(B) is a perspective view as seen from a rear side;

FIG. 7 is a perspective view illustrating a notebook personal computer to which the display apparatus according to the embodiment is applied;

FIG. 8 is a perspective view illustrating a video camera to which the display apparatus according to the embodiment is applied;

FIG. 9 is a diagram illustrating a portable terminal apparatus, for example, a portable phone to which the display apparatus according to the embodiment is applied, and FIG. 9(A) is an elevation view in an unclosed state, FIG. 9(B) is a lateral view thereof, FIG. 9(C) is an elevation view in a closed state, FIG. 9(D) is a left side view, FIG. 9(E) is a right side view, FIG. 9(F) is a top view, and FIG. 9(G) is a bottom view;

FIG. 10A is an explanatory drawing for explaining fabrication steps of organic EL display apparatuses in EXPERIMENTAL EXAMPLE 3;

FIG. 10B is an explanatory drawing for explaining the fabrication steps of the organic EL display apparatuses in EXPERIMENTAL EXAMPLE 3;

FIG. 10C is an explanatory drawing for explaining the fabrication steps of the organic EL display apparatuses in EXPERIMENTAL EXAMPLE 3;

FIG. 10D is an explanatory drawing for explaining the fabrication steps of the organic EL display apparatuses in EXPERIMENTAL EXAMPLE 3;

FIG. 11 is a cross-sectional view illustrating an organic EL element according to SECOND EMBODIMENT;

FIG. 12 is a cross-sectional view illustrating an exemplary configuration of an organic layer in the organic EL element according to SECOND EMBODIMENT;

FIG. 13 is a cross-sectional view for explaining a reason for no short circuits between a first electrode and a second electrode even in case of foreign matter on the first electrode in the organic EL element according to SECOND EMBODIMENT;

FIG. 14 is a schematic diagram illustrating transmission spectra according to change in thickness of a second resistance layer, a thickness of a first resistance layer being fixed to 500 nm, in the organic EL element according to SECOND EMBODIMENT;

FIG. 15 is a schematic diagram illustrating chromaticity view angle characteristics according to change in thickness of the second resistance layer, the thickness of the first resistance layer being fixed to 500 nm, in the organic EL element according to SECOND EMBODIMENT;

FIG. 16 is a schematic diagram illustrating chromaticity view angle characteristics according to change in total thickness of a first resistance layer and second resistance layer ranging ±10%, the thickness of the second resistance layer being fixed to 0 nm, in the organic EL element according to SECOND EMBODIMENT;

FIG. 17 is a schematic diagram illustrating chromaticity view angle characteristics according to change in total thickness of the first resistance layer and second resistance layer ranging ±10%, the thickness of the second resistance layer being fixed to 1000 nm, in the organic EL element according to SECOND EMBODIMENT;

FIG. 18 is a schematic diagram illustrating voltage-current density characteristics of two kinds of organic EL elements different in configuration of the first resistance layer and second resistance layer from each other in SECOND EMBODIMENT;

FIG. 19 is a cross-sectional view illustrating a display apparatus according to FOURTH EMBODIMENT;

FIG. 20 is a cross-sectional view illustrating a display apparatus according to FOURTH EMBODIMENT in a module shape with a sealed structure;

FIG. 21 is a perspective view illustrating a television device to which the display apparatus according to FOURTH EMBODIMENT is applied;

FIG. 22 is a perspective view illustrating a digital camera to which the display apparatus according to FOURTH EMBODIMENT is applied;

FIG. 23 is a perspective view illustrating a notebook personal computer to which the display apparatus according to FOURTH EMBODIMENT is applied;

FIG. 24 is a perspective view illustrating a video camera to which the display apparatus according to FOURTH EMBODIMENT is applied;

FIG. 25 is a perspective view illustrating a portable phone to which the display apparatus according to FOURTH EMBODIMENT is applied;

FIG. 26 is a perspective view illustrating a digital single-lens reflex camera to which the display apparatus according to FOURTH EMBODIMENT is applied;

FIG. 27 is a perspective view illustrating a head mounted display to which the display apparatus according to FOURTH EMBODIMENT is applied;

FIG. 28 is a cross-sectional view illustrating an organic EL lighting apparatus according to FIFTH EMBODIMENT; and

FIG. 29 is a cross-sectional view for explaining short circuits between a first electrode and a second electrode caused by foreign matter present on the first electrode in an existing organic EL element.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Incidentally, the description is made in the following order.

### (1) FIRST EMBODIMENT

(1-1) Configuration of Light Emitting Element

(1-2) Configuration of Display Apparatus

(1-3) Cross-Sectional Exemplary Configuration of Display Apparatus

(1-4) Application Examples

### (2) EXAMPLES

### 2. SECOND EMBODIMENT (Organic EL Element and Manufacturing Method Thereof)

### 3. THIRD EMBODIMENT (Organic EL Element and Manufacturing Method Thereof)

### 4. FOURTH EMBODIMENT (Display Apparatus)

### 5. FIFTH EMBODIMENT (Lighting Apparatus)

### First Embodiment

### <Configuration of Light Emitting Element>

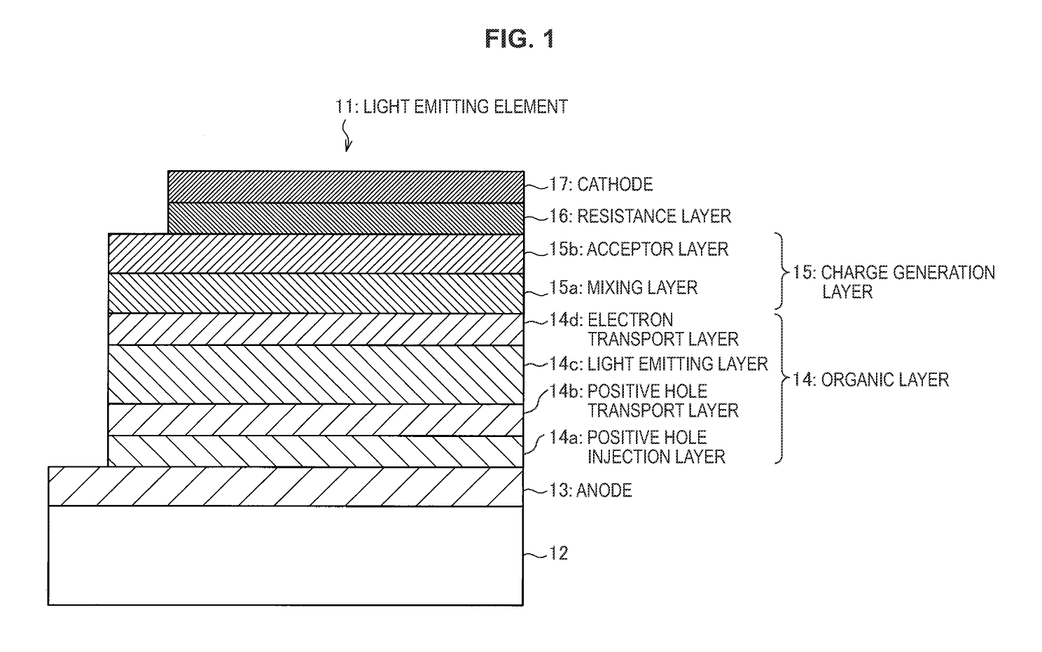

First, a configuration of an organic electroluminescent element according to a first embodiment of the present disclosure (hereinafter, also referred to as a light emitting element) is described in detail with reference to FIG. 1. FIG. 1 is a schematic cross-sectional view of a light emitting element according to the embodiment.

As illustrated in FIG. 1, on a substrate 12, an anode 13 is formed, an organic layer 14 is formed on the anode 13, a charge generation layer 15 is formed on the organic layer 14, a resistance layer 16 is formed on the charge generation layer 15, and a cathode 17 is formed on the resistance layer 16, these affording a light emitting element 11 according to the embodiment.

Incidentally, language “a B layer formed on an A layer” is used as above, and it is supposed that such language also includes a B layer formed on one or more different layers, where the one or more layers that are different from the B layer are formed immediately on an A layer, other than a B layer formed immediately on an A layer.

Hereafter, it is supposed that the light emitting element 11 having the configuration as illustrated in FIG. 1 is a so-called top emission element in which light is taken from the side opposite to the substrate 12, and the details of the individual layers are described sequentially from the substrate 12 side.

### [Substrate]

The substrate 12 is a supporting body on one principal plane side of which light emitting elements 11 are formed and arranged. This substrate 12 can employ a know one, for example, a high strain point glass substrate, a soda-lime glass (Na₂O.CaO.SiO₂) substrate, a borosilicate glass (Na₂O.B₂O₃.SiO₂) substrate, a forsterite (2MgO.SiO₂) substrate, a lead glass (Na₂O.PbO.SiO₂) substrate, various glass substrates on whose surface an insulation film is formed, a quartz substrate, a quartz substrate on whose surface an insulation film is formed, a silicon substrate on whose surface an insulation film is formed, an organic polymer (in a form of a macromolecular material such as a flexible plastic film, plastic sheet and plastic substrate which are made of a macromolecular material) such, for example, as poly(methyl methacrylate) (PMMA), poly(vinyl alcohol) (PVA), poly(vinyl phenol) (PVP), poly(ether sulfone) (PES), polyimide, polycarbonate, poly(ethylene telephthalate) (PET).

In addition, the substrate 12 itself is not expected to be transparent as long as a top emission structure is employed in which light is taken from the side opposite to the substrate 12, and it may employ, for example, a substrate made of single crystal silicon. Moreover, an active drive display apparatus configured of the light emitting elements 11 employs a substrate in which active elements for driving the light emitting elements 11 are formed.

### [Anode]

The anode 13 as one example of the first electrode is an electrode used for injecting holes to the organic layer 14 of the light emitting element 11. Since the light emitting element 11 according to the embodiment is a top emission element, the anode 13 according to the embodiment reflects light emitted from a light emitting layer 14c mentioned later. Formation of this anode 13 employs an electrode material large in work function from a vacuum level in order to inject holes efficiently. Examples of such an electrode material can include, for example, metal and alloy large in work function such as platinum (Pt), gold (Au), silver (Ag), chromium (Cr), tungsten (W), nickel (Ni), copper (Cu), iron (Fe), cobalt (Co) and tantalum (Ta) (for example, Ag—Pd—Cu alloy containing silver as a primary component, 0.3 wt. % to 1 wt. % of palladium (Pd) and 0.3 wt. % to 1 wt. % of copper (Cu), and Al—Nd alloy). Furthermore, in case of a conductive material small in work function and high in optical reflectance such as aluminum (Al) and alloy containing aluminum, it can be used as the anode 13 by improving ability of hole injection due to providing an appropriate positive hole injection layer or the like. Herein, a thickness of the anode 13 can be, for example, 0.1 μm to 1 μm.

Moreover, a structure can also be employed which is obtained by layering a transparent conductive material excellent in hole injection characteristics such as indium tin oxide (ITO) and indium zinc oxide (IZO) on a reflective layer high in optical reflectivity such as a dielectric multilayer and aluminum (Al).

In addition, the anode 13 may include a conductive layer which is on the side in contact with the substrate 12 and is for improving close contact of the anode 13 with the substrate 12. Such a conductive layer can include a transparent conductive layer such as ITO and IZO.

Moreover, when the display apparatus is configured of the light emitting elements 11 and driven in an active matrix manner, the anode 13 is formed by patterning for each pixel and provided in connection with a thin film transistor for driving provided in the substrate 12. Moreover, although omitted from the figure in this case, an insulation film is provided on the anode 13, and the surface of the anode 13 for each pixel is exposed from each of aperture parts of this insulation film.

### [Organic Layer]

The organic layer 14 according to the embodiment is formed on the anode 13, and at least includes a light emitting layer made of organic light emitting material. This organic layer 14 may be formed of only a light emitting layer, or may be formed of a plurality of layers including a light emitting layer, for example, as illustrated in FIG. 1.

The organic layer 14 according to the embodiment mainly includes a positive hole injection layer 14a layered on the anode 13, a positive hole transport layer 14b layered on the positive hole injection layer 14a, a light emitting layer 14c layered on the positive hole transport layer 14b, and an electron transport layer 14d layered on the light emitting layer 14c, for example, as illustrated in FIG. 1.

Positive Hole Injection Layer 14a and Positive Hole Transport Layer 14b

The positive hole injection layer 14a and positive hole transport layer 14b are layers formed for enhancing hole injection efficiency to the light emitting layer 14c, respectively. Examples of materials used for forming the positive hole injection layer 14a or the positive hole transport layer 14b may include, for example, benzene, styrylamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenon, hydrazone, stilbene, and derivatives thereof. Or examples of a material for the positive hole injection layer 14a or the positive hole transport layer 14b can also include polysilane compounds, and heterocyclic conjugated monomers, oligomers or polymers such as vinylcarbazole compounds, thiophene compounds, and aniline compounds.

Further specific compounds for the positive hole injection layer 14a or the positive hole transport layer 14b mentioned above can include, for example, α-naphthylphenylphenylenediamine, porphyrin, metal tetraphenylporphyrine, metal naphthalocyanine, hexacyanoazatriphenylene, 7,7,8,8-tetracyanoquinodimethane (TCNQ), 7,7,8,8-tetracyano-2,3,5,6-tetrafluoroquinodimethane (F4-TCNQ), tetracyano-4,4,4-tris(3-methylphenylphenylamino)triphenylamine, N,N,N′,N′-tetrakis(p-tolyl)p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophenevinylene), poly(2,2′-thienylpyrrole), and the like, whereas compounds used for the positive hole injection layer 14a and positive hole transport layer 14b according to the embodiment are not limited to these.

Light Emitting Layer 14c

The light emitting layer 14c provides a region in which holes injected from the anode 13 and electrons injected from the cathode 17 are recombined, and thereby, emission of light is conducted, at least including material having light emitting function. Moreover, the light emitting layer 14c is preferably configured using material having an injection function and a transport function of charge. The injection function is a function by which, while holes can be injected from the anode 13, positive hole injection layer 14a or positive hole transport layer 14b during application of an electric field, electrons can be injected from the electron transport layer 14d or a charge generation layer 15 mentioned later. Moreover, the transport function is a function of moving the injected holes and electrons due to the electric field.

The light emitting layer 14c as above can be configured of a light emitting material (dopant) included in a host material.

The host material can include, for example, styryl derivatives, anthracene derivatives, naphthacene derivatives, and aromatic amines Especially preferably, the styryl derivative is at least one kind selected from distyryl derivatives, tristyryl derivatives, tetrastyryl derivatives, and styrylamine derivatives. Compounds as the host material can be appropriately selected in consideration of carrier balance of the whole light emitting element 11 according to the embodiment, and the like.

Moreover, as the light emitting material, known fluorescent materials can be used. The fluorescent materials can be selected, for example, from fluorescent materials such as laser dyes such as styrylbenzene dyes, oxazole dyes, perylene dyes, coumarin dyes and acridine dyes, polyaromatic hydrocarbon materials such as anthracene derivatives, naphthacene derivatives, pentacene derivatives and chrysene derivatives, pyrromethene skeleton compounds and metal complexes thereof, quinacridone derivatives, cyanomethylenepyran derivatives (DCM, DCJTB and the like), benzothiazole compounds, benzoimidazole compounds and metal-chelated oxynoid compounds. Each of these fluorescent materials is preferably, for example, at a dope concentration of 0.5% or higher and 15% or lower in film thickness ratio.

In addition, examples of the light emitting material are not limited to the fluorescent materials but may be known phosphorescent materials.

Electron Transport Layer 14d

The electron transport layer 14d is a layer formed for enhancing electron injection efficiency to the light emitting layer 14c. Examples of a compound used for forming this electron transport layer 14d can include known compounds with an electron transport property and can include, for example, anthracene derivatives, phenanthroline derivatives, silol derivatives, and ones having an azaaryl skeleton and containing alkali metals, alkali earth metals, or metals, oxides and composite oxides of lanhtanides, fluoride materials.

Moreover, examples of a compound used for forming the electron transport layer 14d may include known metal complexes and benzimidazole derivatives such as Alq3. Benzimidazole derivatives usable for the electron transport layer can include, for example, compounds as disclosed in Japanese Patent Laid-Open No. 2010-092960.

Usage of the compounds mentioned above for the electron transport layer 14d is preferable to be able to inject sufficient electrons to light emitting layer 14c efficiently. Thereby, its combination with the light emitting layer 14c having the above-mentioned configuration enable to localize the recombination region and to make the injection factor (injection balance between electrons and holes to the light emitting layer 14c) γ closer to 1, this leading to high efficiency and further longer lifetime.

Specific examples of the above-described compounds used for the electron transport layer 14d include the following compounds, whereas the electron transport materials usable for the light emitting element 11 according to the embodiment are not limited to the following examples.

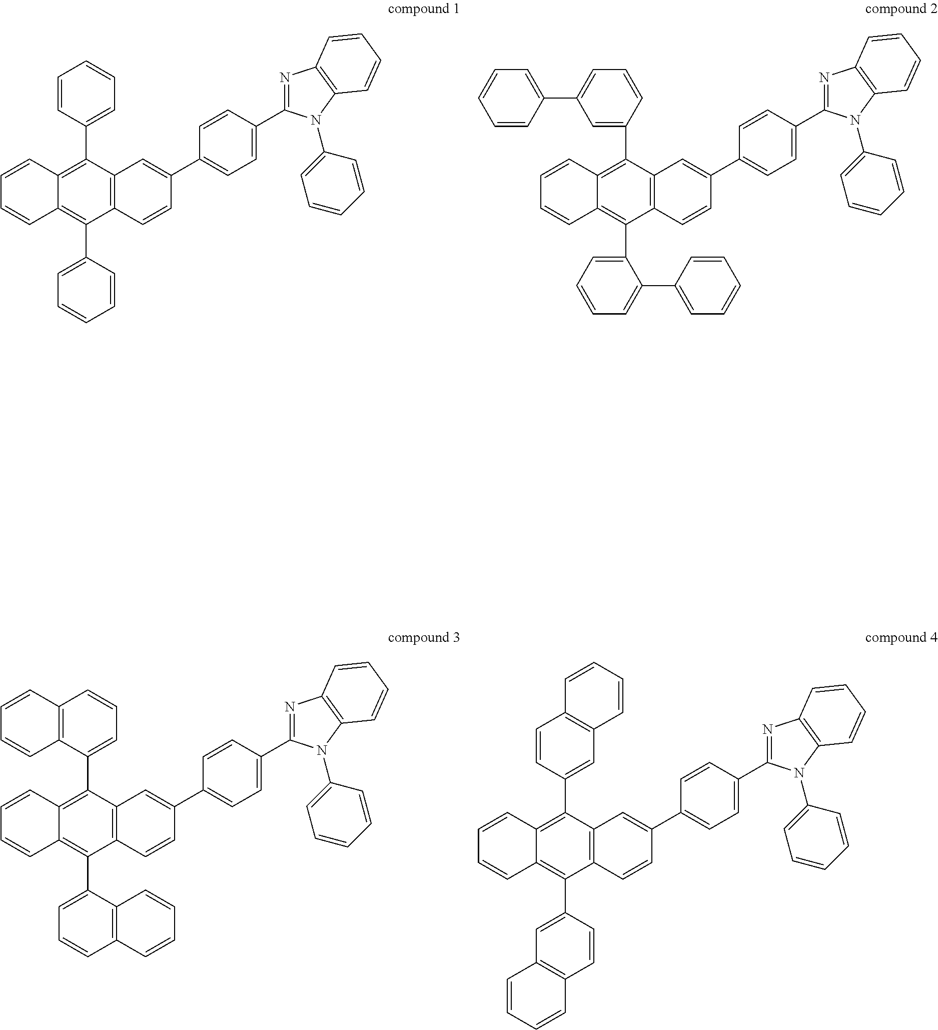 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2cccc(-c3c4ccccc4c(-c4ccccc4-c4ccccc4)c4ccc(-c5ccc(-c6nc7ccccc7n6-c6ccccc6)cc5)cc34)c2)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

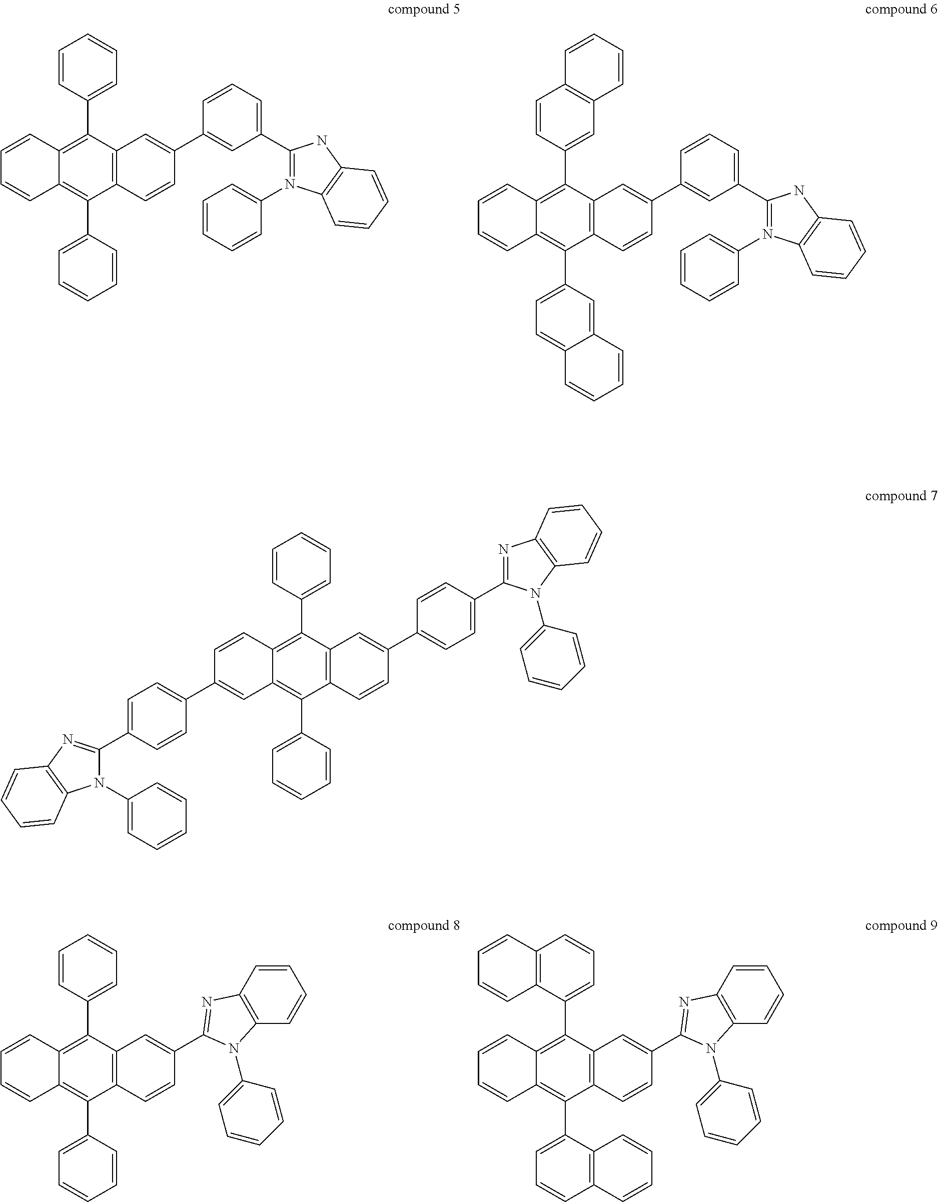

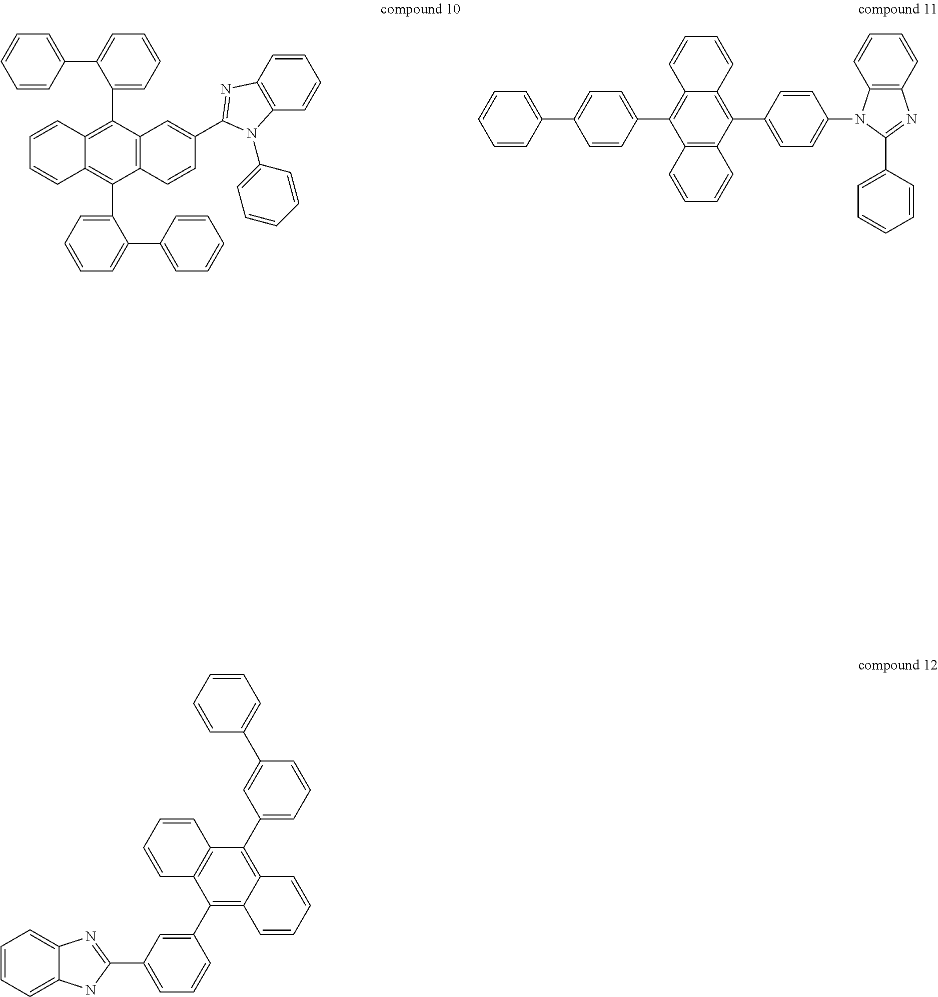 [SMILES: c1ccc(-c2ccccc2-c2c3ccccc3c(-c3ccccc3-c3ccccc3)c3cc(-c4nc5ccccc5n4-c4ccccc4)ccc23)cc1 ; c1ccc(-c2ccc(-c3c4ccccc4c(-c4ccc(-n5c(-c6ccccc6)nc6ccccc65)cc4)c4ccccc34)cc2)cc1 ; c1ccc(-c2cccc(-c3c4ccccc4c(-c4cccc(-c5nc6ccccc6[nH]5)c4)c4ccccc34)c2)cc1]

As above, the organic layer 14 included in the light emitting element 11 according to the embodiment has been described in detail.

### [Charge Generation Layer]

In voltage application, the charge generation layer 15 according to the embodiment injects, while injecting holes to the layer of the charge generation layer 15 disposed on the cathode 17 side, electrons to the organic layer 14 disposed on the anode 13 side of the charge generation layer 15. In this case, the charge generation layer 15 is useful for a stacked light emitting element in which two kinds of organic layers (specifically, two kinds of light emitting layers) are formed interposing the charge generation layer 15.

As illustrated in FIG. 1, this charge generation layer 15 includes a mixing layer 15a and an acceptor layer 15b sequentially in the order from the organic layer 14 side.

Mixing Layer 15a

The mixing layer 15a according to the embodiment injects electrons to the layer adjacent to the organic layer 14 side of the mixing layer 15a. This mixing layer 15a contains a chelate material, and an alkali earth metal or an alkali metal element. Preferably, the alkali earth metal element or the alkali metal element used for the mixing layer 15a is Li or Cs.

Preferably, a mixing ratio of the chelate material to the alkali earth metal element or the alkali metal element is 1:5 to 2:1 in molar ratio. An increase of the alkali earth metal element or the alkali metal element beyond the above-mentioned range is not preferable because electrons are easy to diffuse excessively. Moreover, a decrease of the alkali earth metal element or the alkali metal element below the above-mentioned range is not preferable because electrons are difficult to be generated for injection to the layer adjacent to the organic layer 14 side.

Examples of the chelate material used for the mixing layer 15a can include known chelate materials as long as they can coordinate to the alkali earth metal element or the alkali metal element, whereas it is preferable to at least contain a phenanthroline derivative containing at least one phenanthroline ring, for example, as indicated by chemical formula 2 below. Since phenanthroline derivatives are compounds having an electron transport property, such a phenanthroline derivative as the chelate material enables to inject the generated electrons efficiently to the layer adjacent to the organic layer 14 side of the mixing layer 15a.

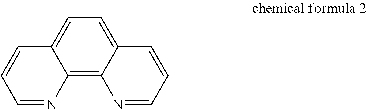 [SMILES: c1cnc2c(c1)ccc1cccnc12]

Specific examples of the above-mentioned phenanthroline derivative can include the compounds indicated below, for example, whereas the phenanthroline derivative according to the embodiment is not limited to the examples below.

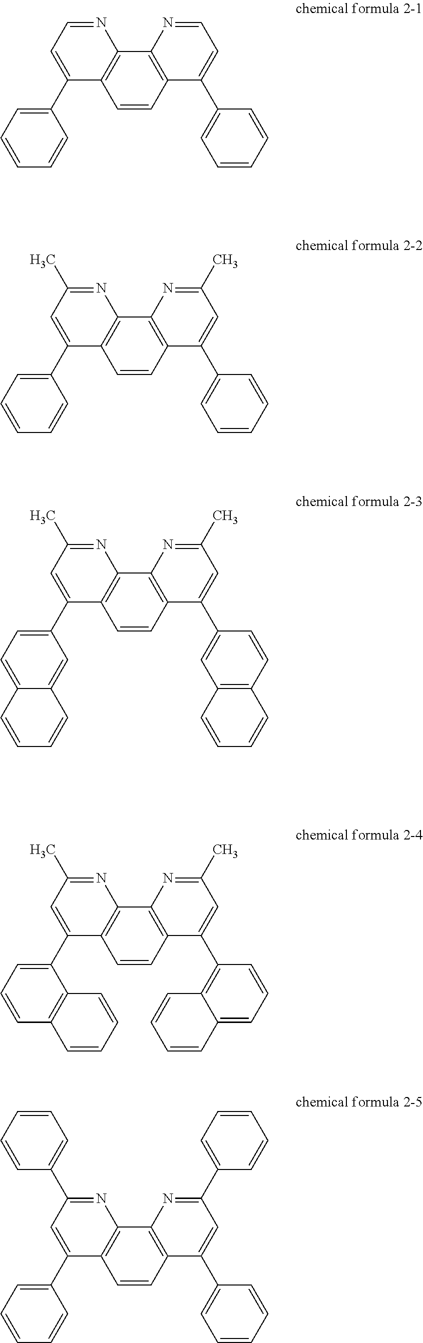 [SMILES: c1ccc(-c2ccnc3c2ccc2c(-c4ccccc4)ccnc23)cc1 ; Cc1cc(-c2ccccc2)c2ccc3c(-c4ccccc4)cc(C)nc3c2n1 ; Cc1cc(-c2ccc3ccccc3c2)c2ccc3c(-c4ccc5ccccc5c4)cc(C)nc3c2n1 ; Cc1cc(-c2cccc3ccccc23)c2ccc3c(-c4cccc5ccccc45)cc(C)nc3c2n1 ; c1ccc(-c2cc(-c3ccccc3)c3ccc4c(-c5ccccc5)cc(-c5ccccc5)nc4c3n2)cc1]

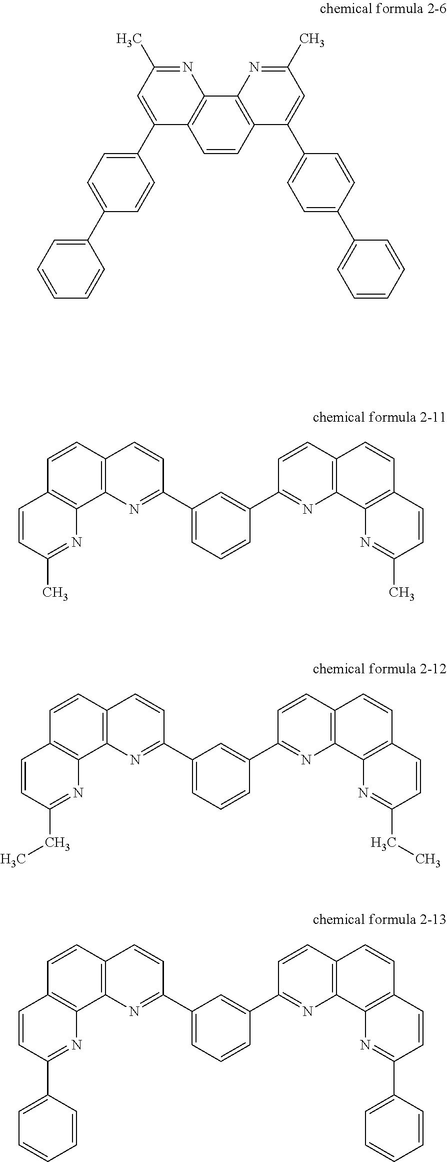 [SMILES: Cc1cc(-c2ccc(-c3ccccc3)cc2)c2ccc3c(-c4ccc(-c5ccccc5)cc4)cc(C)nc3c2n1 ; Cc1ccc2ccc3ccc(-c4cccc(-c5ccc6ccc7ccc(C)nc7c6n5)c4)nc3c2n1 ; CCc1ccc2ccc3ccc(-c4cccc(-c5ccc6ccc7ccc(CC)nc7c6n5)c4)nc3c2n1 ; c1ccc(-c2ccc3ccc4ccc(-c5cccc(-c6ccc7ccc8ccc(-c9ccccc9)nc8c7n6)c5)nc4c3n2)cc1]

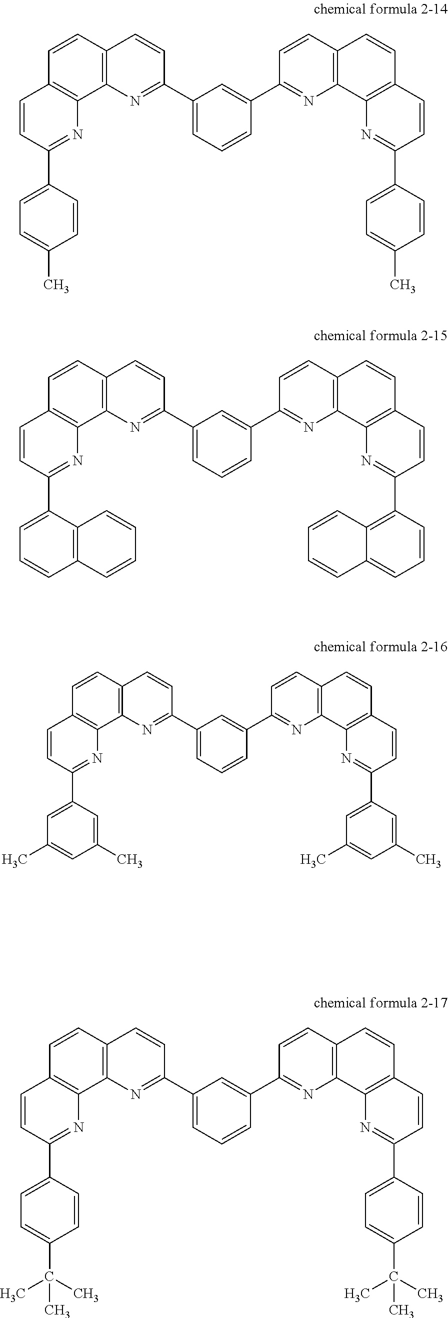

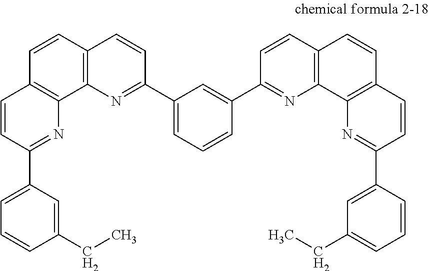 [SMILES: CCc1cccc(-c2ccc3ccc4ccc(-c5cccc(-c6ccc7ccc8ccc(-c9cccc(CC)c9)nc8c7n6)c5)nc4c3n2)c1]

Acceptor Layer 15b

The acceptor layer 15b according to the embodiment is a layer generating holes according to voltage application, and contains an acceptor material.

Examples of the acceptor material forming the acceptor layer 15b can include, for example, known oxide semiconductors such as molybdenum oxide (MoO₃), and compounds indicated by chemical formula 1 below.

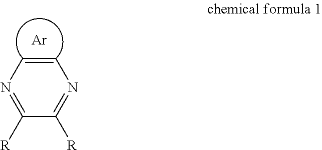

In chemical formula 1 above, Ar represents an aryl group, and each R independently represents a hydrogen atom, an alkyl group having 1 to 10 carbon atoms, an alkyloxy group having 1 to 10 carbon atoms, a group having 1 to 10 carbon atoms, a halogen element, a cyano group, or a substituted or unsubstituted silyl group.

Further detailed examples of the compound indicated by chemical formula 1 above can include azatriphenylene derivatives having a skeleton as indicated by (chemical formula 1-1) below.

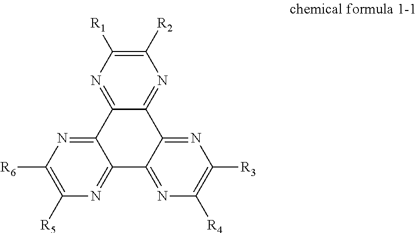

In (chemical formula 1-1) above, R1 to R6 each independently represents a hydrogen atom, an alkyl group having 1 to 10 carbon atoms, an alkyloxy group having 1 to 10 carbon atoms, a group having 1 to 10 carbon atoms, a halogen element, a cyano group, or a substituted or unsubstituted silyl group.

Providing the charge generation layer 15 as mentioned above enables sufficient and excellent charge balance in a transparent electrode element capable of attaining wide view angles and high definition, high light emission efficiency and stable driving, and reduction of damage on organic films caused by particles with high energy entering them in formation of transparent electrodes.

### [Resistance Layer]

The resistance layer 16 according to the embodiment is made of a material having an electric resistivity from 1×10² Ω·cm to 1×10⁶ Ω·cm. Preferably, the resistance layer 16 has a thickness of 0.1 μm to 2 μm, preferably, 0.3 μm to 1 μm above the organic layer 14. The electric resistivity less than 1×10² Ω·cm is not preferable because short circuits can arise, and the electric resistivity more than 1×10⁶ Ω·cm is not preferable because the light emitting element 11 according to the embodiment does not possibly function as an electroluminescent element. Moreover, the resistance layer 16 having the thickness of 0.1 μm to 2 μm can prevent short circuits caused by contaminants such as organic matter attaching during layer formation.

Preferably, the resistance layer 16 according to the embodiment is formed of oxide semiconductor. Examples of such oxide semiconductor can include niobium oxide (Nb₂O₅), titanium oxide (TiO₂), molybdenum oxide (MoO₂, MoO₃), tantalum oxide (Ta₂O₅), hafnium oxide (HfO), indium gallium zinc oxide (IGZO), a mixture of niobium oxide and titanium oxide, a mixture of titanium oxide and zinc oxide (ZnO), a mixture of silicon oxide (SiO₂) and tin oxide (SnO₂), and an appropriate combination of these.

In addition, the electric resistivity of the material included in the resistance layer 16 may, more specifically, be determined in consideration of the value of voltage drop arising in the resistance layer 16 during driving of the light emitting element or in the light emitting element. A typical value of such voltage drop is 0.05 V to 1.0V, for example.

Moreover, the resistance layer 16 according to the embodiment may include a first resistance layer and a second resistance layer stacked sequentially in the order from the organic layer 14 side, having a layered structure thereof, and the second resistance layer may have a higher electric resistivity than the first resistance layer. Moreover, the resistance layer 16 may include a first resistance layer, a second resistance layer and a third resistance layer stacked sequentially in the order from the organic layer 14 side, having a layered structure, and the second resistance layer may have a higher electric resistivity than the first resistance layer and have a higher electric resistivity than the third resistance layer. Herein, examples of materials included in the first resistance layer and third resistance layer can include zinc oxide, tin oxide, niobium oxide, titanium oxide, molybdenum oxide, tantalum oxide, a mixture of niobium oxide and titanium oxide, a mixture of titanium oxide and zinc oxide, and a mixture of silicon oxide and tin oxide, which are formed into films by film deposition at a low partial pressure of oxygen during the film deposition. Moreover, examples of a material included in the second resistance layer can include niobium oxide, titanium oxide, molybdenum oxide, tantalum oxide, a mixture of niobium oxide and titanium oxide, a mixture of titanium oxide and zinc oxide, and a mixture of silicon oxide and tin oxide.

Preferably, the first resistance layer, second resistance layer and third resistance layer have electric resistivities R1 (Ω·cm), R2 (Ω·cm) and R3 (Ω·cm), for example, satisfying:

1×10⁻³≦R1/R2≦1×10⁻¹

1×10⁻³≦R3/R2≦1×10⁻¹

The resistance layer 16 with the multilayer structure provides good contact between the resistance layer 16 and charge generation layer 15, thereby reducing voltage drop across the resistance layer 16 and reducing driving voltage.

Moreover, the resistance layer 16 includes at least the first resistance layer and second resistance layer in a layered structure, the first resistance layer is made of a material having a refractive index n1, the second resistance layer is made of a material having a refractive index n2, and the uppermost layer of the organic layer 14 is made of a material having a refractive index n0, preferably satisfying:

−0.60≦n0−n1≦−0.4

0.4≦n1−n2≦0.9

(in case where importance is attached to efficiency), or

−0.2≦n0−n1≦0.2

0.2≦n1−n2≦0.4

(in case where importance is attached to a view angle)

### [Cathode]

The cathode 17 as one example of the second electrode is an electrode used for injecting electrons to the organic layer 14 of light emitting element 11. Since the light emitting element 11 according to the embodiment is a top emission element, the cathode 17 according to the embodiment transmits light emitted from the light emitting layer 14. Preferably, formation of this cathode 17 employs a conductive material which transmits emitted light and is small in work function from a vacuum level in order to inject electrons to the organic layer 14. Examples of such a conductive material can include, for example, magnesium-silver alloy, and metal or alloy of aluminum, silver, calcium, strontium and the like. An appropriate electron injection layer may be provided on a transparent electrode material made of ITO or IZO to improve an electron injection property. Herein, a thickness of the cathode 17 is 2×10⁻⁹ m to 5×10⁻⁸ m, preferably, 3×10⁻⁹ m to 2×10⁻⁸ m, more preferably, 5×10⁻⁹ m to 1×10⁻⁸ m. Moreover, a bus electrode (auxiliary electrode) made of a low resistance material may be provided with respect to the cathode 17 to reduce the resistance over the whole cathode.

### [Formation Methods of Individual Layers]

Formation of the anode 13 and cathode 17 out of the individual layers included in the light emitting element 11 according to the embodiment can employ, for example, deposition methods such as an electron beam deposition method, a hot filament deposition method and a vacuum deposition method, combinations of an etching method with a sputtering method, a chemical vapor deposition method (CVD method) and an ion plating method, various printing methods such as a screen printing method, an inkjet printing method and a metal mask printing method, plating methods (an electroplating method and an electroless plating method), a lift-off method, a laser ablation method, a sol-gel method, and the like.

The various printing methods and plating methods can form the anode 13 and cathode 17 having desired shapes (patterns) directly. In addition, preferably, formation of the electrode after the formation of the organic layer 14 employs a film formation method in which the energy of film deposition particles is low such as the vacuum deposition method, or a film formation method such as a MOCVD method, in view of preventing damage on the organic layer 14. The damage on the organic layer 14 possibly causes non-light emitting pixels called “dark defects” based on leak current (or non-light emitting sub-pixels). It is preferable to perform the formation of the organic layer 14 to the formation of these electrodes and the like without their exposure to the air, in view of preventing deterioration of the organic layer 14 caused by moisture in the air.

Preferably, the resistance layer 16 is formed by film deposition using a film deposition method excellent in coverage such, for example, as the sputtering method, CVD method and ion plating method.

Formation of the individual layers included in the organic layer 14 can employ a physical vapor deposition method (PVD method) such as the vacuum deposition method, the printing method such as the screen printing method and inkjet printing method, a laser transfer method in which an organic layer on a laser absorption layer is separated and the organic layer is transferred by irradiating a layered structure of the laser absorption layer and organic layer formed on a transfer substrate with laser, and various coating methods. In addition, formation of the organic layer 14 using the vacuum deposition method can include, for example, using a so-called metal mask, depositing material passing through apertures provided in this metal mask, and thereby, forming the organic layer 14.

In addition, the formation methods of the individual layers as mentioned above are just examples, and the formation methods of the individual layers included in the light emitting element 11 according to the embodiment are not limited to the methods mentioned above.

As above, the configuration of the light emitting element 11 according to the embodiment has been described in detail.

In addition, the light emitting element 11 according to the embodiment described above can also be applied to a stacked organic electroluminescent element formed by stacking units of the organic layers 14 having the light emitting layers 14c. Herein, the stacked one is a multi-photon emission element (MPE element), and, for example, Japanese Patent Laid-Open No. 11-329748 discloses an element in which a plurality of organic light emitting elements are joined electrically in series through an intermediate conductive layer

Moreover, Japanese Patent Laid-Open No. 2003-045676 and Japanese Patent Laid-Open No. 2003-272860 disclose element configurations for realizing the multi-photon emission element (MPE element) and detailed examples. According to these, stacking two units of the organic layers can attain two times of luminance [cd/A] without change in light emission efficiency [lm/W] ideally, and stacking three layers can attain three times of luminance [cd/A] without change in light emission efficiency [lm/W] ideally.

Accordingly, using the light emitting element 11 according to the embodiment for this stacked one can attain an element with extremely long lifetime based on the synergistic effect in combination of long lifetime based on improved efficiency in the stacked one with the long-lifetime effects according to the embodiment. In this case, between the charge generation layer 15 and resistance layer 16 illustrated in FIG. 1, a second organic layer including a second light emitting layer, a second charge generation layer, . . . , sequentially in the order from the charge generation layer 15 side are to be formed.

### <Configuration of Display Apparatus>

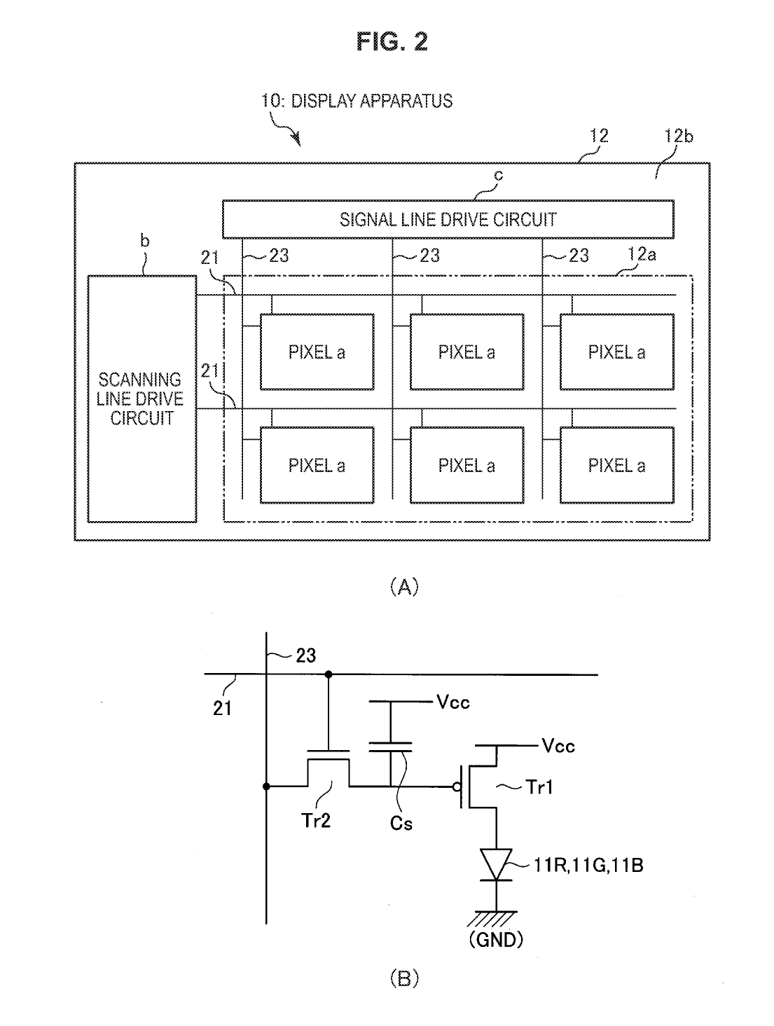

FIGS. 2(A) and 2(B) are diagrams illustrating one example of a display apparatus 10 according to the embodiment. FIG. 2(A) is a schematic configuration diagram, and FIG. 2(B) is a configuration diagram of a pixel circuit. Herein, an example in which the light emitting element 11 according to the embodiment is applied to the active matrix display apparatus 10 using an organic electroluminescent element is described.

As illustrated in FIG. 2(A), a display region 12a and a surrounding region 12b thereof are set on the substrate 12 of the display apparatus 10. The display region 12a includes a plurality of scanning lines 21 and a plurality of signal lines 23, these disposed vertically and horizontally, and is configured as a pixel array section in which one pixel a is provided corresponding to each of the intersections. In each pixel a, one of a red light emitting element 11R, a green light emitting element 11G and a blue light emitting element 11B which have the similar configuration to the light emitting element 11 according to the embodiment is provided. Moreover, the surrounding region 12b includes a scanning line drive circuit b scanning and driving the scanning line 21, and a signal line drive circuit c supplying a picture signal (that is, an input signal) corresponding to luminance information to the signal line 23, these disposed in it.

As illustrated in FIG. 2(B), for example, the pixel circuit provided in each pixel a includes the one of the individual light emitting elements 11R, 11G and 11B, a drive transistor Tr1, a write transistor (sampling transistor) Tr2, and a retention capacity Cs. Furthermore, the picture signal written from the signal line 23 through the write transistor Tr2 is held in the retention capacity Cs by drive of the scanning line drive circuit b, and a current corresponding to the held signal amount is supplied to each of the light emitting elements 11R, 11G and 11B. Each of the light emitting elements 11R, 11G and 11B emits light at a luminance corresponding to this current value.

In addition, the structure of the pixel circuit mentioned above is just one example. If expected, the pixel circuit may be configured by providing a capacitance element, and further, providing a plurality of transistors in the pixel circuit. Moreover, an expected drive circuit is added to the surrounding region 2b according to changes of the pixel circuit.

### <Cross-Sectional Exemplary Configuration of Display Apparatus>

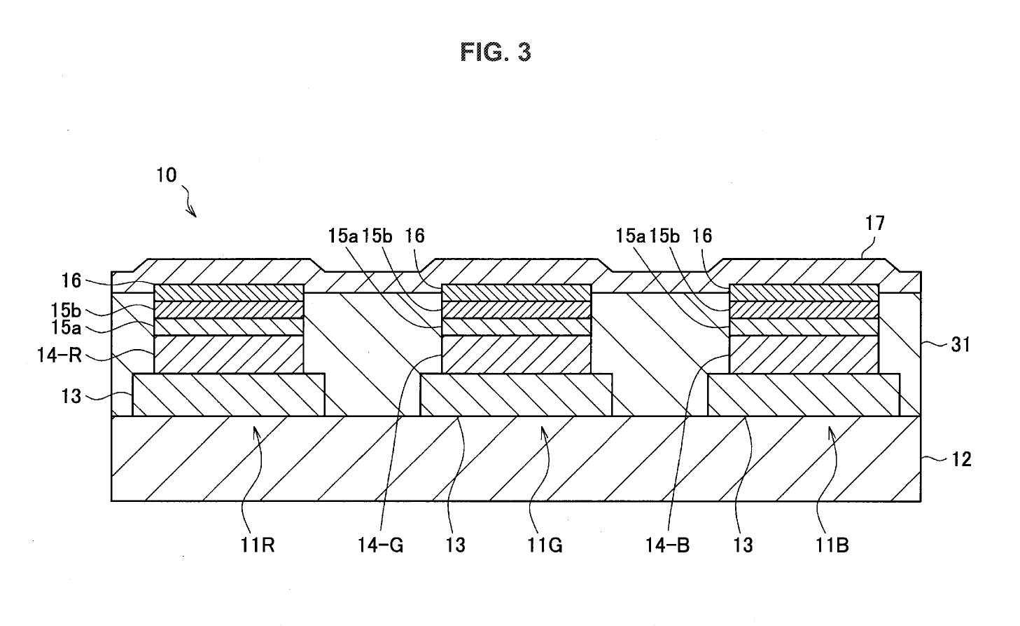

FIG. 3 illustrates a cross-sectional exemplary configuration of the main part in the display region of the above-mentioned display apparatus 10.

In the display region of the substrate 12 in which the organic electroluminescent elements 11R, 11G and 11B are to be provided, although omitted here in the figure, the drive transistor, write transistor, scanning lines and signal lines are provided to be included in the above-mentioned pixel circuit (refer to FIGS. 2(A) and 2(B)), and an insulation film is provided in the state of covering these.

The organic electroluminescent elements 11R, 11G and 11B are formed and aligned on the substrate 12 covered with this insulating film. Each of the organic electroluminescent elements 11R, 11G and 11B is configured as a top emission type element in which light is extracted from the opposite side to the substrate 12.

The anode 13 of each of the organic electroluminescent elements 11R, 11G and 11B is pattern-formed for each element. Each anode 13 is connected to the drive transistor of the pixel circuit through a connection hole formed in the insulating film covering the surface of the substrate 12.

In each anode 13, its surrounding portion is covered with the insulating film 31, and a middle portion of the anode 13 is exposed to an aperture portion provided in the insulating film 31. Then, the organic layer 14 is pattern-formed in the state of covering the exposed portion of the anode 13, and the cathode 17 is provided as a common layer covering each organic layer 14.

Each of the organic electroluminescent elements 11R, 11G and 11B is configured as the above-mentioned organic electroluminescent element (11) according to this embodiment described with reference to FIG. 1.

Furthermore, the plurality of organic electroluminescent elements 11R, 11G and 11B provided in the above-mentioned manner are covered with a protective film. In addition, this protective film is, for example, provided to cover the whole display region in which the organic electroluminescent elements 11R, 11G and 11B are provided.

Herein, each layer from the anode 13 to the cathode 17 included in the red light emitting element 11R, green light emitting element 11G and blue light emitting element 11B can be formed by a dry process such, as mentioned above, as a vacuum deposition method, an ion beam method (EB method), a molecular beam epitaxy method (MBE method), a sputtering method and an OVPD (Organic Vapor Phase Deposition) method.

Moreover, if it is an organic layer, in addition to the above-mentioned methods, formation by a laser transfer method, a wet process including a coating method such as a spin coating method, a dipping method, a doctor blade method, a discharge coating method and a spray coating method, and a printing method such as an inkjet method, an offset printing method, an anastatic printing method, an intaglio printing method, a screen printing method and a micro gravure coating method is possible, and a dry process and a wet process may be used in combination according to characteristics of each organic layer and each member.

Then, the organic layer 14 pattern-formed for each of the organic electroluminescent elements 11R, 11G and 11B in the above-mentioned manner is, for example, formed by a deposition method and a transfer method by using a mask.

Moreover, luminance lifetime can be improved, and an effect of reducing power consumption is brought in the display apparatus 10 by using the organic electroluminescent element 11 having high light emission efficiency as mentioned in the embodiment. Accordingly, the display apparatus 10 can be suitably used as a flat panel display such as a wall-hung television and a flat light emitting body, and application to a light source such as a copy machine and a printer, a light source for a liquid crystal display, an instrument and the like, a display board, a marker light, and the like is possible.

Moreover, in the above-mentioned example, although the embodiment in which the light emitting element according to the embodiment is applied to the active matrix display apparatus has been described, the display apparatus according to the embodiment is applicable to a passive matrix display apparatus, and it is possible to attain the similar effects to those in this case.

In addition, in each of the organic electroluminescent elements 11R, 11G and 11B, layers other than the light emitting layer 14c may be used in common. Moreover, in each of organic electroluminescent elements 11R, 11G and 11B, the electron transport layers 14d and charge generation layers 15 including different materials from one another may be provided so as to be suitable for each of light emitting layers 14c-R, 14c-G and 14c-B.

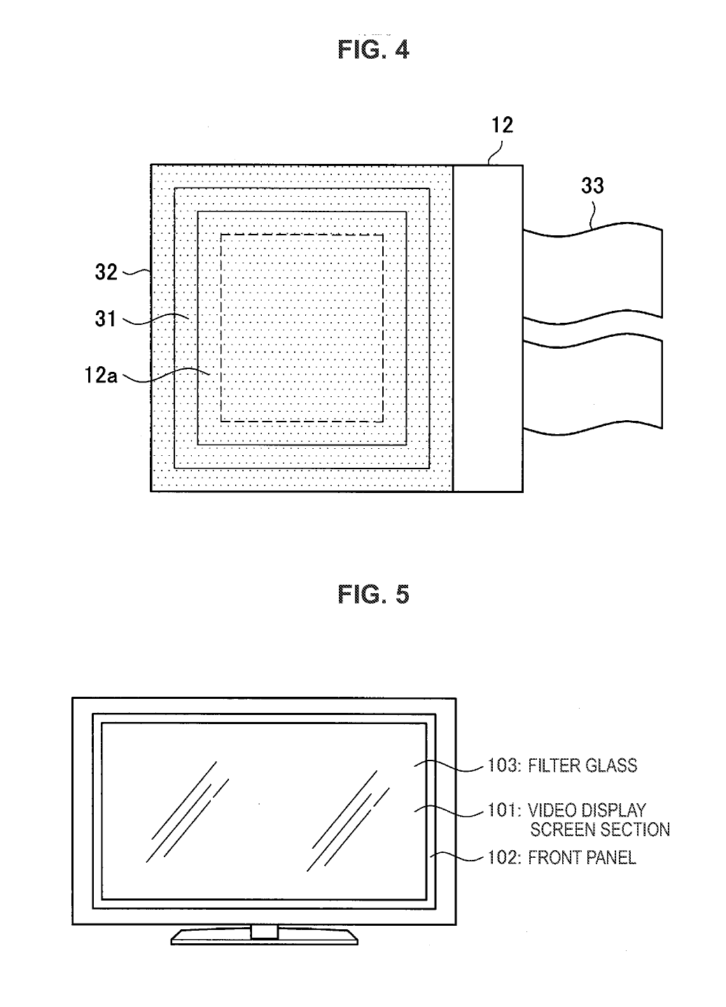

The above-mentioned display apparatus according to the embodiment include one having a module shape with a sealed structure as illustrated in FIG. 4. For example, a display module in which a sealing section 31 is provided so as to surround the display region 12a as a pixel array section and which is bonded to a facing section (a sealing substrate 32) such as transparent glass by the sealing section 31 as an adhesive corresponds to the example. A color filter, a protective film, a light shielding film and the like may be provided in the transparent sealing substrate 32. In addition, a flexible print board 33 for inputting/outputting a signal and the like from outside to the display region 12a (the pixel array section) may be provided in the substrate 12 as the display module in which the display region 12a is formed.

### Application Examples

Moreover, the above-mentioned display apparatus according to the embodiment is applicable to display apparatuses in electronic equipment in various fields for displaying a picture signal inputted to the electronic equipment or a picture signal generated inside the electronic equipment as an image or a picture, such as various kinds of electronic equipment illustrated in FIGS. 5 to 9 such, for example, as a digital camera, a notebook personal computer, a portable terminal device such as a portable phone, and a video camera. Hereafter, examples of electronic equipment to which the display apparatus according to the embodiment is applied are described.

FIG. 5 is a perspective view of a television device to which the display apparatus according to the embodiment is applied. The television device according to the examples of application includes a video display screen section 101 including a front panel 102, a filter glass 103 and the like, and is fabricated by using the display apparatus according to the embodiment as the video display screen section 101.

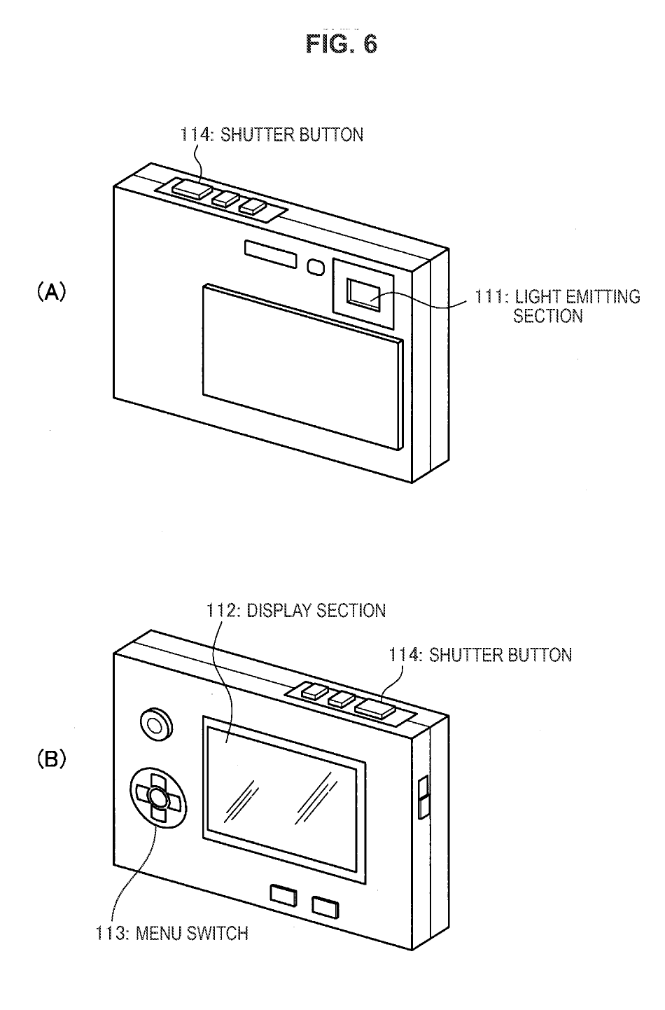

FIG. 6 is a diagram illustrating a digital camera to which the display apparatus according to the embodiment is applied, and FIG. 6(A) is a perspective view as seen from a front side and FIG. 6(B) is a perspective view as seen from a rear side. The digital camera according to the application example includes a light emitting section 111 for a flash, a display section 112, a menu switch 113, a shutter button 114 and the like, and is fabricated by using the display apparatus according to the embodiment as the display section 112.

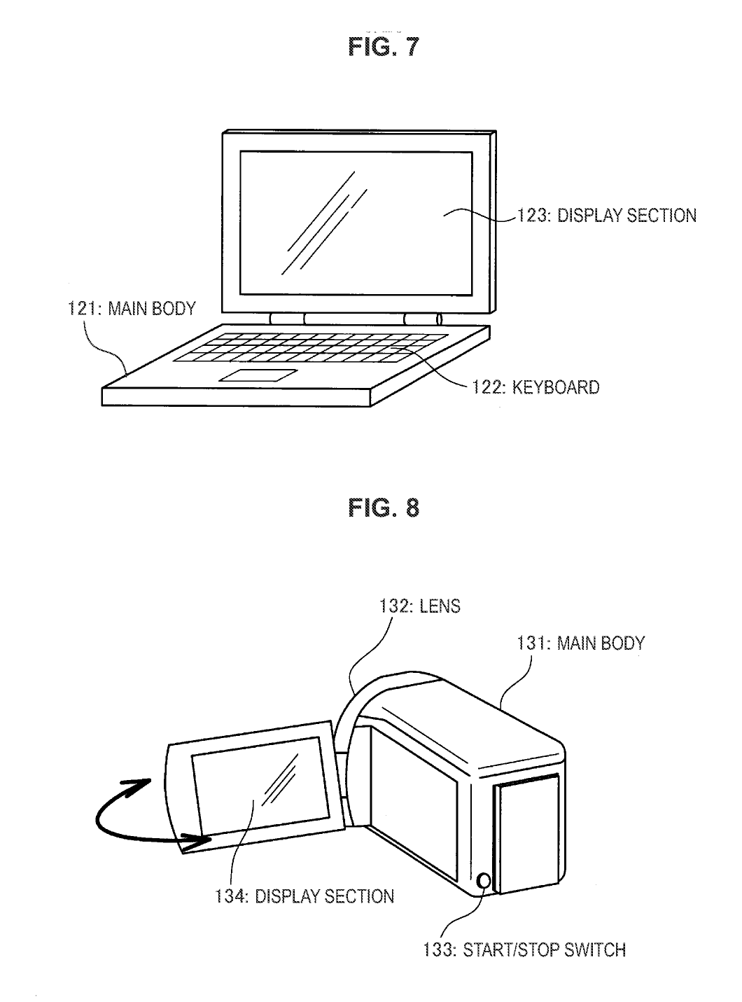

FIG. 7 is a perspective view illustrating a notebook personal computer to which the display apparatus according to the embodiment is applied. The notebook personal computer according to the application example includes a main body 121, a keyboard 122 for operation of inputting characters and the like, a display section 123 for displaying an image, and the like, and is fabricated by using the display apparatus according to the embodiment as the display section 123.

FIG. 8 is a perspective view illustrating a video camera to which the display apparatus according to the embodiment is applied. The video camera according to the application example includes a main body 131, a lens 132 for capturing an image of the subject provided on the front side face thereof, a start/stop switch 133 in capturing an image, a display section 134, and the like, and is fabricated by using the display apparatus according to the embodiment as the display section 134.

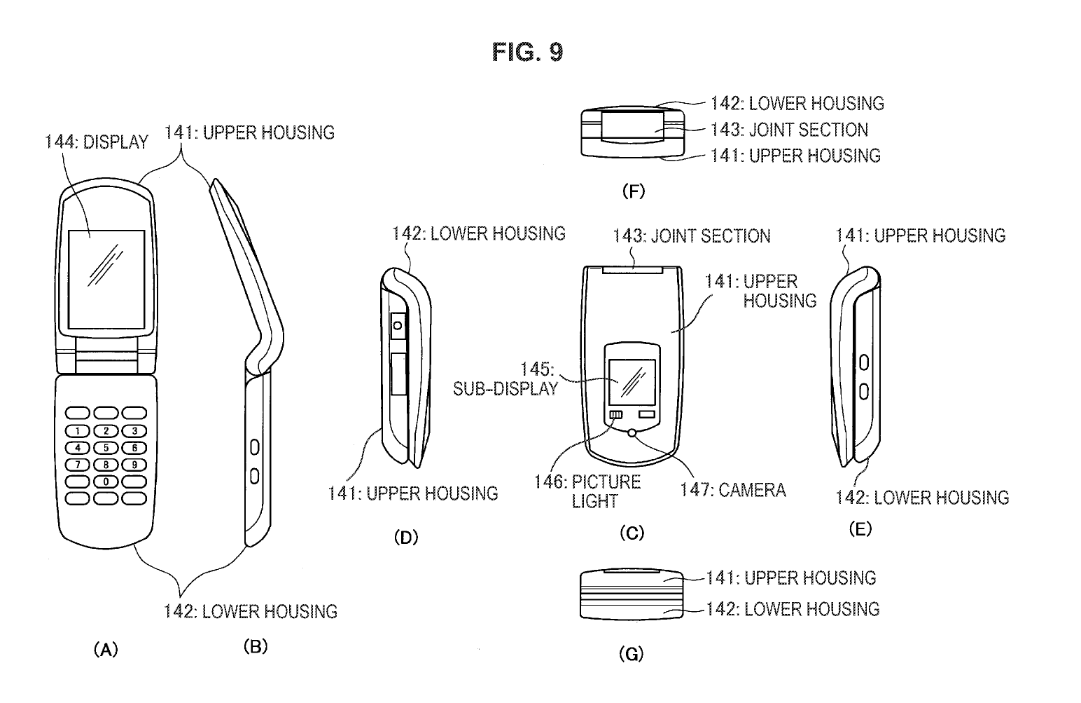

FIG. 9 is a diagram illustrating a portable terminal apparatus, for example, a portable phone to which the display apparatus according to the embodiment is applied, and FIG. 9(A) is an elevation view in an unclosed state, FIG. 9(B) is a lateral view thereof, FIG. 9(C) is an elevation view in a closed state, FIG. 9(D) is a left side view, FIG. 9(E) is a right side view, FIG. 9(F) is a top view, and FIG. 9(G) is a bottom view. The portable phone according to the application example includes an upper housing 141 and a lower housing 142, a joint section (herein, a hinge section) 143, a display 144, a sub-display 145, a picture light 146, a camera 147, and the like, and is fabricated by using the display apparatus according to the embodiment as the display 144 and the sub-display 145.

### EXAMPLES

Hereafter, the light emitting element according to the embodiment of the present disclosure is described, exemplified by examples. However, the light emitting element according to the embodiment of the present disclosure is not limited to content of the examples described below.

### Experimental Example 1

Hereafter, manufacturing methods of the light emitting elements used in examples and comparative examples in EXPERIMENTAL EXAMPLE 1 and an evaluation method of those are described. First, an aluminum (Al) layer with a film thickness of 200 nm was formed as the anode 13 on the substrate 12 made from a glass plate of 30 mm×30 mm, and after that, a portion other than a light emitting region of 2 mm×2 mm was masked with an insulation film due to SiO₂ deposition, affording a cell for the organic electroluminescent element.

### Example 1

As illustrated in Table 1 below, a film of hexanitrileazatriphenylene (hereinafter abbreviated to HATCN6) with a thickness of 10 nm represented by chemical formula 101 below was formed as the positive hole injection layer 14a on the anode 13 of the fabricated cell.

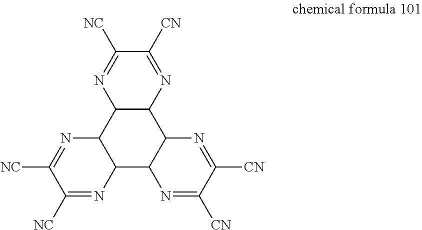 [SMILES: N#CC1=NC2C3N=C(C#N)C(C#N)=NC3C3N=C(C#N)C(C#N)=NC3C2N=C1C#N]

Subsequently, a blue light emitting unit was fabricated as the organic layer 14. More in detail, a film of TPD with a thickness of 90 nm represented by chemical formula 102 below (deposition rate: 0.2-0.4 nm/sec) was formed as the positive hole transport layer 14b on the above-mentioned positive hole injection layer 14a due to the vacuum deposition method.

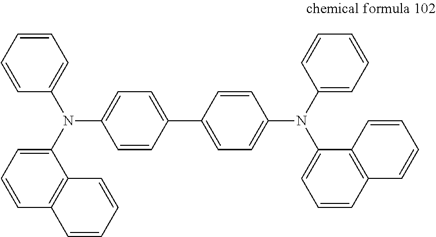 [SMILES: c1ccc(N(c2ccc(-c3ccc(N(c4ccccc4)c4cccc5ccccc45)cc3)cc2)c2cccc3ccccc23)cc1]

After that, setting the compound represented by chemical formula 103 below as a host and the compound represented by chemical formula 104 below as a dopant, a film of these compounds with a total thickness of 30 nm was formed by film deposition as the light emitting layer 14c so as to have 5% of film thickness ratio due to the vacuum deposition method.

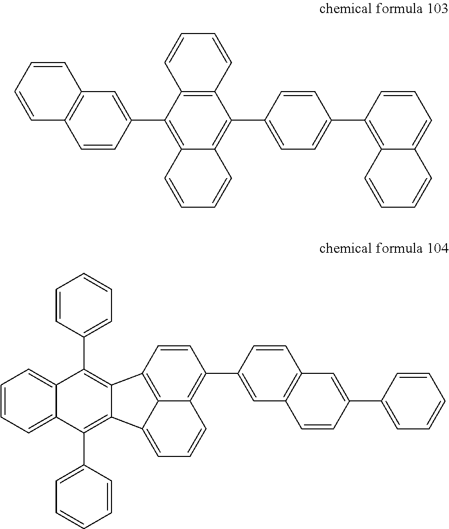

Next, a film of Alq3 represented by chemical formula 105 with a thickness of 30 nm was formed as the electron transport layer 14d on the above-mentioned light emitting layer 14c, affording the blue light emitting unit.

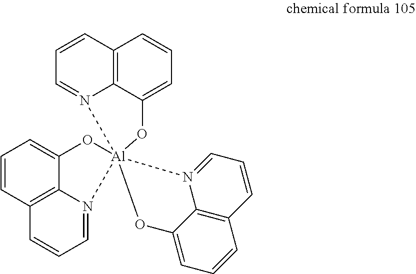

On the organic layer 14 as described above, using the above-mentioned phenanthroline derivative in (chemical formula 2-15) and cesium (Cs), a film with a total thickness of 10 nm was formed at 1:1 of molar ratio between the phenanthroline derivative and Cs, affording the mixing layer 15a. After that, on the mixing layer 15a, a film of HATCN6 with a thickness of 20 nm represented by chemical formula 101 mentioned above was formed, affording the acceptor layer 15b.

Subsequently, on the above-mentioned acceptor layer 15b, a film of niobium oxide (Nb₂O₅) with a thickness of approximately 300 nm was formed by sputtering, affording the resistance layer 16. After that, on the resistance layer 16, a film of IZO with a thickness of 100 nm was formed by the vacuum deposition method, affording the cathode 17.

In addition, a measurement of the electric resistivity of the formed resistance layer 16 was 5×10⁵ [Ω·cm].

### Example 2

A light emitting element was fabricated similarly to Example 1 mentioned above except that the phenanthroline derivative used for the mixing layer 15a was the above-mentioned phenanthroline derivative in (chemical formula 2-12) and the cathode was formed using ITO.

In addition, a measurement of the electric resistivity of the formed resistance layer 16 was 5×10⁵ [Q·cm].

### Comparative Example 1

A light emitting element was fabricated similarly to Example 1 except that the mixing layer 15a, acceptor layer 15b and resistance layer 16 were not formed and the cathode was formed using ITO.

### Comparative Example 2

A light emitting element was fabricated similarly to Example 1 except that the phenanthroline derivative used for the mixing layer 15a was the above-mentioned phenanthroline derivative in (chemical formula 2-13), the acceptor layer 15b and resistance layer 16 were not formed, and the cathode was formed using ITO.

### Comparative Example 3

A film with a total thickness of 10 nm using Alq and magnesium (Mg) was formed at 1:1 of molar ratio between Alq and Mg, affording the mixing layer 15a. Thus, a light emitting element was fabricated similarly to Example 1 except that a film with a thickness of 20 nm of HATCN6 represented by chemical formula 101 mentioned above was formed on the mixing layer 15a, the resistance layer 16 was not formed, and the cathode was formed using ITO.

The configurations of the electrodes, charge generation layer and resistance layer of the light emitting elements fabricated in EXPERIMENTAL EXAMPLE 1 as above are illustrated collectively in Table 1 below.

TABLE 1

| | | Charge Generation Layer | | | |
|---|---|---|---|---|---|
| | Anode | Mixing Layer | Acceptor Layer | Resistance Layer | Cathode |
| Example 1 | Al 200 nm | (Chemical Formula 2-15) + Cs (1:1) 10 nm | HATCN6 20 nm | Nb₂O₅ 300 nm | IZO 100 nm |
| Example 2 | Al 200 nm | (Chemical Formula 2-12) + Cs (1:1) 10 nm | HATCN6 20 nm | Nb₂O₅ 300 nm | ITO 100 nm |
| Comparative Example 1 | Al 200 nm | N/A | N/A | N/A | ITO 100 nm |
| Comparative Example 2 | Al 200 nm | (Chemical Formula2-13) + Cs (1:1) 10 nm | N/A | N/A | ITO 100 nm |
| Comparative Example 3 | Al 200 nm | Alq + Mg (1:1) 10 nm | HATCN6 20 nm | N/A | ITO 100 nm |

### <Evaluation Method>

Voltages (V) and efficiencies (cd/A) at a current density of 10 m A/cm² were measured for the light emitting elements fabricated as mentioned above in Examples and Comparative Examples. Moreover, relative luminances after elapse of 1000 hours relative to initial luminances set as 1 in constant current driving at 50° C. and 30 mA/cm² were measured, and in addition, elevations from initial voltages after the elapse of 1000 hours were measured.

The given results are illustrated in Table 2 below.

TABLE 2

| | | | | Voltage |
|---|---|---|---|---|
| | Efficiency | Voltage | Luminance | Elevation |
| | [cd/A] | [V] | [%] | [V] |
| Example 1 | 15 | 6 | 95 | 0.05 |
| Example 2 | 13 | 6 | 85 | 0.1 |
| Comparative Example 1 | No Light Emission | | | |
| Comparative Example 2 | 0.5 | 15 | Lifetime Measurement | |
| | | | Not Available | |
| Comparative Example 3 | 2 | 5.5 | 30 | 10 |

As apparent from Table 2 above, the light emitting elements according to the embodiment of the present disclosure brought stable driving with high efficiency. On the other hand, Comparative Example 1 in which the charge generation layer and resistance layer were not formed resulted in leakage and did not bring emission of light. Moreover, Comparative Example 2 in which the acceptor layer and resistance layer were not formed resulted in inability of the electron injection from the cathode 17 and hardly brought emission of light, and therefore, lifetime measurement was significantly difficult to be performed. Moreover, Comparative Example 3 in which only the electron injection layer was formed and the resistance layer was not formed resulted in inability of the electron injection and hardly brought emission of light.

### Experimental Example 2

Hereafter, manufacturing methods of the light emitting elements used in examples and comparative examples in EXPERIMENTAL EXAMPLE 2 and an evaluation method of those are described. First, an aluminum (Al) layer with a film thickness of 200 nm was formed as the anode 13 on the substrate 12 made from a glass plate of 30 mm×30 mm, and after that, a portion other than a light emitting region of 2 mm×2 mm was masked with an insulation film due to SiO₂ deposition, affording a cell for the organic electroluminescent element.

### Example 3

As illustrated in Table 2 below, a film of hexanitrileazatriphenylene (HATCN6) with a thickness of 10 nm represented by chemical formula 101 mentioned above was formed as the positive hole injection layer 14a on the anode 13 of the fabricated cell.

Subsequently, a blue light emitting unit was fabricated as a first organic layer 14. More in detail, a film of TPD with a thickness of 20 nm represented by chemical formula 102 mentioned above (deposition rate: 0.2-0.4 nm/sec) was formed as a first positive hole transport layer 14b on the above-mentioned positive hole injection layer 14a due to the vacuum deposition method.

After that, setting the compound represented by chemical formula III below as a host and the compound represented by chemical formula 112 below as a dopant, a film of these compounds with a total thickness of 20 nm was formed by film deposition as the first light emitting layer (Blue light emitting layer) 14c so as to have 5% of film thickness ratio due to the vacuum deposition method.

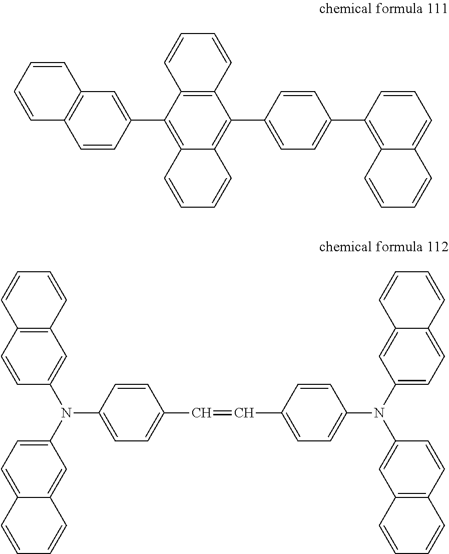

Next, a film of the compound represented by chemical formula 113 with a thickness of 30 nm was formed as the electron transport layer (ETL) 14d on the above-mentioned first light emitting layer 14c, affording the first organic layer 14.

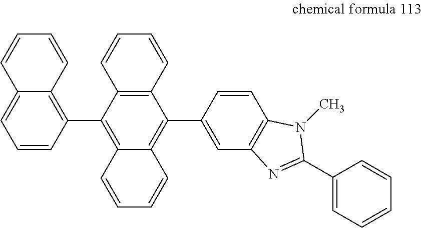 [SMILES: Cn1c(-c2ccccc2)nc2cc(-c3c4ccccc4c(-c4cccc5ccccc45)c4ccccc34)ccc21]

On the first organic layer 14 as described above, using the above-mentioned phenanthroline derivative in (chemical formula 2-11) and lithium (Li), a film with a total thickness of 10 nm was formed at 1:1 of molar ratio between the phenanthroline derivative and Li, affording the first mixing layer 15a. After that, on the first mixing layer 15a, a film of HATCN6 with a thickness of 20 nm represented by chemical formula 101 mentioned above was formed, affording a first acceptor layer 15b. These first mixing layer 15a and first acceptor layer 15b are included in a first charge generation layer 15.

Subsequently, on the first charge generation layer 15, a red light emitting unit and a green light emitting unit were fabricated as a second organic layer 14. More in detail, a film of TPD with a thickness of 20 nm represented by chemical formula 102 mentioned above (deposition rate: 0.2-0.4 nm/sec) was formed as a second positive hole transport layer 14b on the above-mentioned first charge generation layer 15 due to the vacuum deposition method.

After that, setting the compound represented by chemical formula 114 below as a host and the compound represented by chemical formula 115 below as a dopant, a film of these compounds with a total thickness of 20 nm was formed by film deposition as a Red light emitting layer so as to have 1% of film thickness ratio due to the vacuum deposition method.

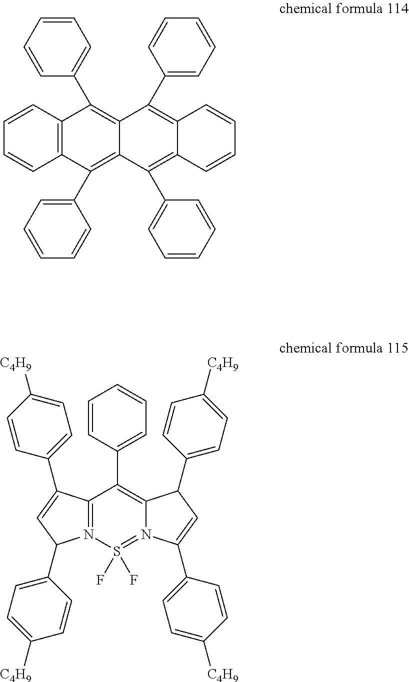

Next, a film of TPD with a thickness of 5 nm represented by chemical formula 102 mentioned above (deposition rate: 0.2-0.4 nm/sec) on the above-mentioned Red light emitting layer due to the vacuum deposition method, affording the red light emitting unit.

Subsequently, setting the compound represented by chemical formula III mentioned above as a host and the compound represented by chemical formula 116 below as a dopant, a film of these compounds with a total thickness of 20 nm was formed by film deposition as a Green light emitting layer so as to have 5% of film thickness ratio on the above-mentioned TPD layer due to the vacuum deposition method.

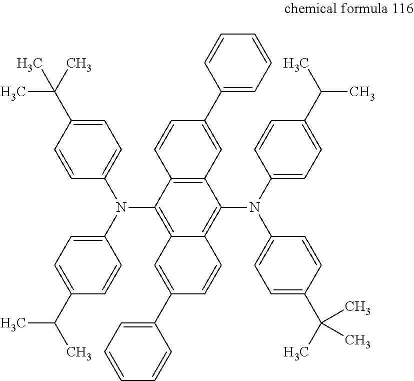 [SMILES: CC(C)c1ccc(N(c2ccc(C(C)(C)C)cc2)c2c3ccc(-c4ccccc4)cc3c(N(c3ccc(C(C)C)cc3)c3ccc(C(C)(C)C)cc3)c3ccc(-c4ccccc4)cc23)cc1]

Next, a film of the compound represented by chemical formula 113 mentioned above with a thickness of 30 nm was formed as the electron transport layer (ETL) 14d on the Green light emitting layer, affording the second organic layer 14.

On the second organic layer 14 as described above, the above-mentioned phenanthroline derivative in (chemical formula 2-11) and lithium (Li), a film with a total thickness of 10 nm was formed at 1:1 of molar ratio between the phenanthroline derivatives and Li, affording the second mixing layer 15a. After that, on the second mixing layer 15a, a film of HATCN6 with a thickness of 20 nm represented by chemical formula 101 mentioned above was formed, affording a second acceptor layer 15b. These second mixing layer 15a and second acceptor layer 15b are included in a second charge generation layer 15.

Subsequently, on the above-mentioned second charge generation layer 15, a film of niobium oxide (Nb₂O₅) with a thickness of approximately 300 nm was formed by sputtering, affording the resistance layer 16. After that, on the resistance layer 16, a film of IZO with a thickness of 100 nm was formed by the vacuum deposition method, affording the cathode 17.

In addition, a measurement of the electric resistivity of the formed resistance layer 16 was 5×10⁵ [Ω·cm].

### Example 4

A light emitting element was fabricated similarly to Example 3 except that both of the substance used for the formation of the positive hole injection layer 14a and the substance used for the formation of the acceptor layer 15b in the second charge generation layer were changed to molybdenum oxide (MoO₃), the substance used for the formation of the mixing layers 15a in the first charge generation layer and second charge generation layer was changed to the above-mentioned phenanthroline derivative in (chemical formula 2-14), and the substance used for the formation of the cathode 17 was changed to ITO.

In addition, a measurement of the electric resistivity of the formed resistance layer 16 was 5×10⁵ [Ω·cm].

### Example 5

A light emitting element was fabricated similarly to Example 3 except that the substance used for the formation of the mixing layers 15a in the first charge generation layer and second charge generation layer was changed to the above-mentioned phenanthroline derivative in (chemical formula 2-17), a film of 80 mol % of zinc oxide (ZnO), 10 mol % of magnesium oxide (MgO) and 10 mol % of aluminum oxide (Al₂O₃) with a thickness of approximately 1000 nm was formed by sputtering as the resistance layer 16 on the above-mentioned second charge generation layer 15, and after that, a film of IZO with a thickness of 100 nm was formed as the cathode 17 by the vacuum deposition method on the resistance layer 16.

In addition, a measurement of the electric resistivity of the formed resistance layer 16 was 1×10⁵ [Ω·cm].

### Comparative Example 4

A light emitting element was fabricated similarly to Example 3 except that films of Alq and magnesium (Mg) with a total thickness of 20 nm were formed as the first mixing layer and second mixing layer at 5% of molar ratio of Mg relative to Alq, after that, a film of HATCN6 with a thickness of 10 nm represented by chemical formula 101 mentioned above was formed on the first mixing layer 15a, the second acceptor layer and resistance layer 16 in the second charge generation layer were not formed, and the cathode was formed using ITO.

The configurations of the electrodes, charge generation layer and resistance layer of the light emitting elements fabricated in EXPERIMENTAL EXAMPLE 2 as above are illustrated collectively in Table 3 below.

TABLE 3

| | | Hole | First Charge Generation Layer | | Second Charge Generation Layer | | | |
|---|---|---|---|---|---|---|---|---|
| | | Injection | | Acceptor | | Acceptor | Resistance | |
| | Anode | Layer | Mixing Layer | Layer | Mixing Layer | Layer | Layer | Cathode |
| Example 3 | Al | HATCN6 | (Chemical Formula 2-11) + | HATCN6 | (Chemical Formula 2-11) + | HATCN6 | Nb₂O₅ | IZO |
| | 200 nm | 10 nm | Li (1:1) 10 nm | 20 nm | Li (1:1) 10 nm | 20 nm | 300 nm | 100 nm |
| Example 4 | Al | MoO₃ | (Chemical Formula 2-14) + | HATCN6 | (Chemical Formula 2-14) + | MoO₃ | Nb₂O₅ | ITO |
| | 200 nm | 10 nm | Li (1:1) 10 nm | 20 nm | Li (1:1) 10 nm | 20 nm | 300 nm | 100 nm |
| Example 5 | Al | HATCN6 | (Chemical Formula 2-17) + | HATCN6 | (Chemical Formula 2-17) + | HATCN6 | ZnO + MgO + | IZO |
| | 200 nm | 10 nm | Li (1:1) 10 nm | 20 nm | Li (1:1) 10 nm | 20 nm | AL₂O₃ | 100 nm |
| | | | | | | | 1000 nm | |
| Comparative | Al | HATCN6 | Alq + Mg (5%) 20 nm | HATCN6 | Alq + Mg (5%) 20 nm | N/A | N/A | ITO |
| Example 4 | 200 nm | 10 nm | | 10 nm | | | | 100 nm |

First Organic Layer: TPD 20 nm/Blue Light Emitting Layer 20 nm/ETL 30 nm
Second Organic Layer: TPD 20 nm/Red Light Emitting Layer 20 nm/TPD 5 nm/Green Light Emitting Layer 20 nm/ETL 30 nm

### <Evaluation Method>

Voltages (V) and efficiencies (cd/A) as a current density of 10 m A/cm² were measured for the light emitting elements fabricated as mentioned above in Examples and Comparative Examples. Moreover, relative luminances after elapse of 1000 hours relative to initial luminances set as 1 in constant current driving at 50° C. and 30 mA/cm² were measured, and in addition, elevations from initial voltages after the elapse of 1000 hours were measured.

The given results are illustrated in Table 4 below.

TABLE 4

| | | | | Voltage |
|---|---|---|---|---|
| | Efficiency | Voltage | Luminance | Elevation |
| | [cd/A] | [V] | [%] | [V] |
| Example 3 | 35 | 10 | 95 | 0.05 |
| Example 4 | 28 | 10 | 85 | 0.1 |
| Example 5 | 33 | 10 | 95 | 0.1 |
| Comparative Example 4 | 12 | 15 | 42 | 2 |

As apparent from Table 4 above, the light emitting elements according to the embodiment of the present disclosure brought stable driving with high efficiency. On the other hand, Comparative Example 4 resulted in inability of the electron injection and hardly brought emission of light.

### Experimental Example 3

### <Evaluation of Number of Defects>

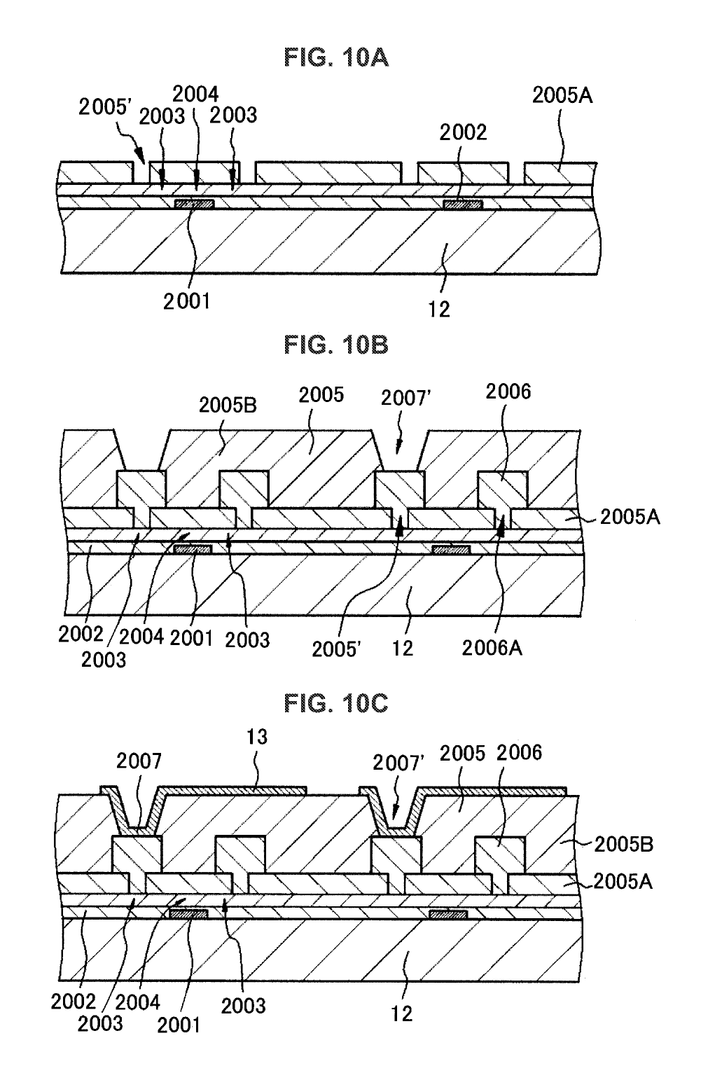

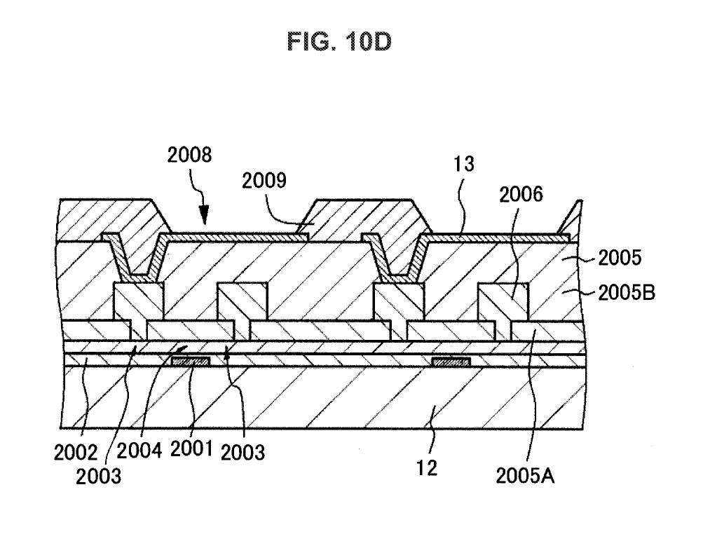

According to the following steps, four organic EL display apparatuses with 460 thousand pixels were fabricated as prototypes, and the total sums of the number of defects (dark defects) were counted for theses four ones. Hereafter, the fabrication steps of the organic EL display apparatus in the examples are first described with reference to FIG. 10A to FIG. 10D.

First, a TFT was fabricated on a first substrate 12 for each sub-pixel based on a known method. The TFT included a gate electrode 2001 formed on the first substrate 12, a gate insulation film 2002 formed on the first substrate 12 and gate electrode 2001, source/drain regions 2003 provided in a semiconductor layer formed on the gate insulation film 2002, and a channel forming region 2004 which was between the source/drain regions 2003 and corresponded to a portion of the semiconductor layer above the gate electrode 2001. In addition, in the example illustrated in FIG. 10A, a bottom gate TFT was employed, whereas a top gate one might be employed. The gate electrode 2001 of the TFT was connected to a scanning circuit (not shown). Next, an underlying interlayer insulation layer 2005A made of SiO₂ was formed by film deposition so as to cover the TFT on the first substrate 12 due to the CVD method, and after that, apertures 2005′ were formed in the underlying interlayer insulation layer 2005A based on the photolithography technique and etching technique (refer to FIG. 10A).

Next, wirings 2006 made of aluminum were formed on the underlying interlayer insulation layer 2005A based on a combination of the vacuum deposition method and etching method. In addition, the wirings 2006 were electrically connected to the source/drain regions 2003 of the TFT through contact plugs 2006A provided in the apertures 2005′. The wiring 2006 were connected to a signal supply circuit (not shown). Subsequently, an overlying interlayer insulation layer 2005B made of SiO₂ was formed by film deposition over the whole area due to the CVD method. Next, apertures 2007′ were formed on the overlying interlayer insulation layer 2005B based on the photolithography technique and etching technique (refer to FIG. 10B).

After that, a first electrode 13 made of Al—Nd alloy was formed on the overlying interlayer insulation layer 2005B based on a combination of the vacuum deposition method and etching method (refer to FIG. 10C). In addition, the first electrode 13 was electrically connected to the wirings 2006 through contact plugs 2007 provided in the apertures 2007′.

Next, an insulation layer 2009 having an aperture part 2008 in which the first electrode 13 exposed on the bottom of the aperture part 2008 was formed on the interlayer insulation layer 2005 including the first electrode 13 (refer to FIG. 10D). Specifically, the insulation layer 2009 made of a polyimide resin with a thickness of 1 μm was formed on the interlayer insulation layer 2005 and on a surrounding portion of the first electrode 13 based on the spin coating method and etching method. In addition, the portion of the insulation layer 2009 that surrounds the aperture part 2008 preferably includes a gentle slope.

Subsequently, any one of films similar to those in Examples 3 to 5 and Comparative Example 4 presented in EXPERIMENTAL EXAMPLE 2 mentioned above (that is, the films in each of which the positive hole injection layer, first organic layer, first charge generation layer, second organic layer, second charge generation layer and resistance layer indicated in Table 3 were formed sequentially) over from the top of the portion of first electrode 13 that exposed on the bottom of the aperture part 2008 to the portion of the insulation layer 2009 that surrounded the aperture part 2008 was formed.

Specifically, setting the insulation layer 2009 as a sort of spacer, a metal mask for forming the above-mentioned organic layer 14 and charge generation layer 15 included in each sub-pixel on the insulation layer 2009 was placed on the projection of the insulation layer 2009, and in this state, each layer was formed by film deposition based on resistance heating. The material included in the organic layer 14 and charge generation layer 15 passed through the aperture provided in the metal mask and deposited over from the top of the portion of the first electrode 13 that exposed on the bottom of the aperture part 2008 included in the sub-pixel to the top of the portion of the insulation layer 2009 that surrounded the aperture part 2008. Subsequently, any one of the resistance layers 16 similar to those of Examples 3 to 5 and Comparative Example 4 presented in EXPERIMENTAL EXAMPLE 2 mentioned above was formed by film deposition due to the sputtering method.

After that, a second electrode 17 was formed on the whole area of the display region fabricated as mentioned above. The second electrode 17 covered the whole area of the organic layer, charge generation layer and resistance layer included in N×M organic EL elements. The second electrode 17, however, was insulated from the first electrode 13 by the above-mentioned resistance layer, organic layer, charge generation layer and insulation layer. The second electrode 17 was also formed based on the magnetron sputtering method which is a film formation method in which film deposition particles have low energy to the extent to which they do not affect the organic layer, charge generation layer and resistance layer.

Next, on the second electrode 17, an insulative protective film made of amorphous silicon nitride (Si₁₋ₓNₓ) was formed based on a plasma CVD method. The formation of the protective film did not expose the second electrode 17 to the air, and by being performed continuously, could prevent deterioration of the organic layer and/or charge generation layer caused by moisture and/or oxygen in the air. After that, the protective film and second substrate were bonded together with an adhesive layer made from an acrylic adhesive. Connection to external circuits, finally, completed the organic EL display apparatus.

Fabricating the organic EL display apparatus as mentioned above conducted preparation of the organic EL display apparatuses each of which had a layer structure similar to any one of those in Examples 3 to 5 and Comparative Example 4 in EXPERIMENTAL EXAMPLE 2 mentioned above. For the four organic EL display apparatuses with 460 thousand pixels thus prepared, total sums of defects (dark defects) were counted. The results were as follows.

Layer Structure Presented in Example 3: 4

Layer Structure Presented in Example 4: 7

Layer Structure Presented in Example 5: 3

Layer Structure Presented in Comparative Example 4: 1080

As apparent from the above-mentioned results, the organic EL display apparatuses with the layer structures in Example 3 to Example 5 brought the significantly small number of defects (number of dark defects) compared with the organic EL display apparatus presented in Comparative Example 4.

As described above, the light emitting element according to the embodiment of the present disclosure enables sufficient and excellent charge balance in a transparent electrode element capable of attaining wide view angles and high definition, high light emission efficiency and stable driving, secure suppression of short circuits between an anode as a first electrode and a cathode as a second electrode, and reduction of damage on organic films caused by particles with high energy entering them in formation of transparent electrodes.

It should be understood by those skilled in the art that various modifications, combinations, sub-combinations and alterations may occur depending on design requirements and other factors insofar as they are within the scope of the appended claims or the equivalents thereof

Incidentally, the following configuration is also with in the technical scope of the present disclosure:

(1) A light emitting element including: a first electrode; an organic layer having a light emitting layer, formed on the first electrode; a charge generation layer formed on the organic layer; a resistance layer formed on the charge generation layer; and a second electrode formed on the resistance layer, wherein the first electrode reflects light emitted from the light emitting layer and the second electrode transmits the light emitted from the light emitting layer, and wherein the charge generation layer includes a layered structure of, sequentially in order from the organic layer side, a mixing layer containing a chelate material, and an alkali earth metal element or an alkali metal element, and an acceptor layer containing an acceptor material;

(2) The light emitting element according to item (1), wherein electric resistivity of a material included in the resistance layer is 1×10² Ω·cm to 1×10⁶ Ω·cm, and wherein a thickness of the resistance layer over the organic layer is 0.1 μm to 2 μm;

(3) The light emitting element according to item (1) or (2), wherein the acceptor layer at least contains a compound represented by chemical formula 1 below:

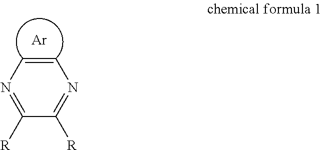

where, in chemical formula 1 above, Ar represents an aryl group and R represents a hydrogen atom, an alkyl group having 1 to 10 carbon atoms, an alkyloxy group having 1 to 10 carbon atoms, a dialkylamine group having 1 to 10 carbon atoms, a halogen element, a cyano group, or a substituted or unsubstituted silyl group;

(4) The light emitting element according to any one of items (1) to (3), wherein the chelate material at least contains a phenanthroline derivative containing at least one phenanthroline ring represented by chemical formula 2 below:

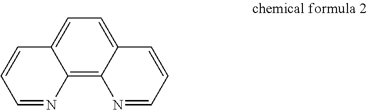 [SMILES: c1cnc2c(c1)ccc1cccnc12]

(5) The light emitting element according to any one of items (1) to (4), wherein the mixing layer contains the chelate material, and one of Li and Cs;

(6) The light emitting element according to item (5), wherein a molar ratio of a mixture of the chelate material, and the alkali earth metal element or the alkali metal element is 1:5 to 2:1 in the mixing layer; and

(7) A display apparatus including a light emitting element including: a first electrode; an organic layer having a light emitting layer, formed on the first electrode; a charge generation layer formed on the organic layer; a resistance layer formed on the charge generation layer; and a second electrode formed on the resistance layer, wherein the first electrode reflects light emitted from the light emitting layer and the second electrode transmits the light emitted from the light emitting layer, and wherein the charge generation layer includes a layered structure of, sequentially in order from the organic layer side, a mixing layer containing a chelate material, and an alkali earth metal element or an alkali metal element, and an acceptor layer containing an acceptor material.

### 2. Second Embodiment

### [Organic EL Element]

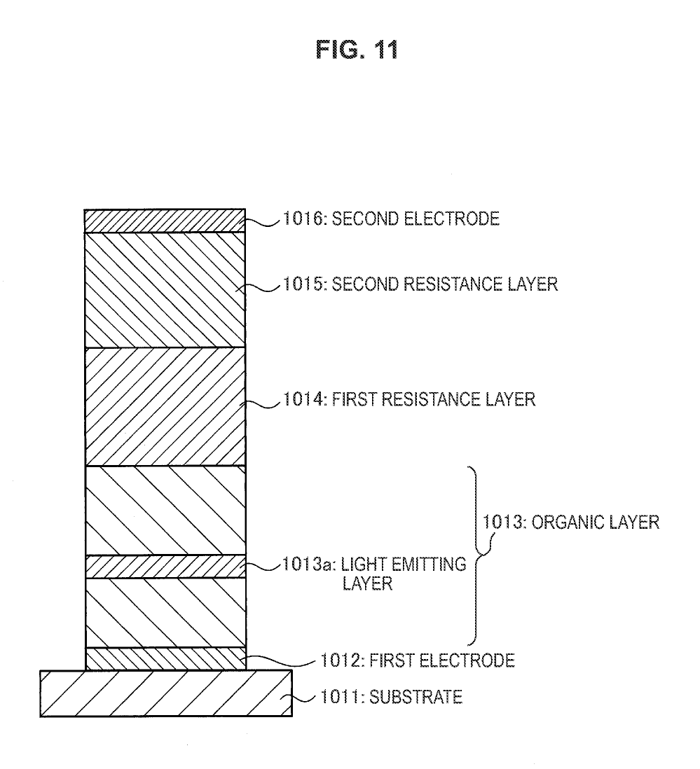

FIG. 11 illustrates an organic EL element according to a second embodiment as a top emission organic EL element.

As illustrated in FIG. 11, on a substrate 1011, this organic EL element includes a first electrode 1012, an organic layer 1013 including a light emitting layer 1013a of an organic light emitting material, a first resistance layer 1014, a second resistance layer 1015 and a second electrode 1016, these sequentially layered in this order from the bottom.

The substrate 1011 may or may not be transparent with respect to light from the light emitting layer 1013a, may or may not be flexible, and may be made from various kinds of materials which are selected as wanted. Specifically, the substrate 1011 is, for example, a transparent or opaque glass substrate, or a semiconductor substrate such as a silicon substrate, whereas it is not limited to these.

The first electrode 1012 is used as both a reflective layer and an anode electrode, and configured, for example, of a light reflective material such as aluminum (Al), aluminum alloy, platinum (Pt), gold (Au), chromium (Cr), and tungsten (W). This first electrode 1012 preferably has a thickness ranging 100 to 300 nm, whereas it is not limited to this. The first electrode 1012 may be a transparent electrode as wanted, and in this case, is preferably provided with a reflective layer made of a light reflective material such, for example, as Pt, Au, Cr and W for the purpose of forming a reflective interface between the first electrode 1012 and substrate 1011.

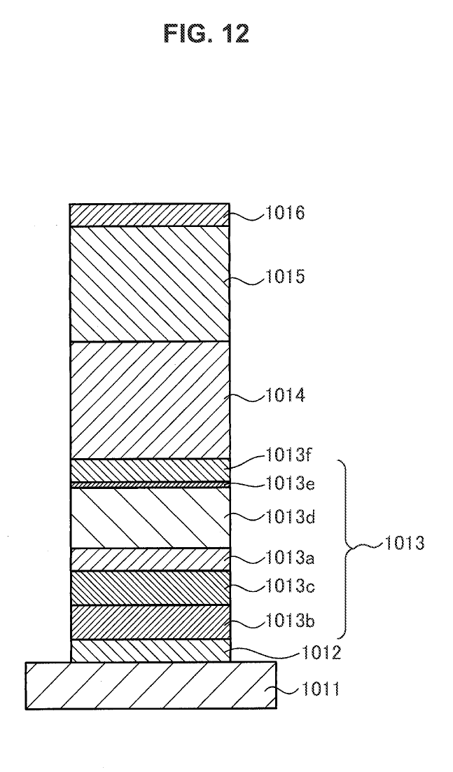

The organic layer 1013 includes a positive hole injection layer, a positive hole transport layer, an electron transport layer, an electron injection layer, a connection layer and the like as wanted, in addition to the light emitting layer 1013a. As one example, FIG. 12 illustrates an organic layer 1013 including a positive hole injection layer 1013b, a positive hole transport layer 1013c, a light emitting layer 1013a, an electron transport layer 1013d, an electron injection layer 1013e and a connection layer 1013f sequentially in the order from the bottom layer, these affording a layered structure.

A light emitting material of the light emitting layer 1013a is selected appropriately according to an emitted light color. A green light emitting material can employ, for example, Alq3 (trisquinolinolatoaluminum complex). A red light emitting material can employ, for example, rubrene as a host material which is doped with a pyrromethene boron complex. A blue light emitting material can employ, for example, ADN (9,10-di(2-naphthyl)anthracene) which is doped with a diaminochrysene derivative as a dopant material at a relative film thickness ratio of 5%. The emitted light color of the light emitting layer 1013a is not limited to be monochromatic, but may be, for example, white color to be emitted due to layering a plurality of light emitting layers different from one another in emitted color or performing co-deposition of a plurality of light emitting material different from one another in emitted light. The positive hole injection layer 1013b is configured, for example, of hexaazatriphenylene (HAT) and the like. The positive hole transport layer 1013c is configured, for example, of α-NPD (N,N′-di(1-naphthyl)-N,N′-diphenyl-(1,1′-biphenyl)-4,4′-diamine) The electron transport layer 1013d is configured, for example, of BCP (2,9-dimethyl-4,7-diphenyl-1,10-phenanthroline) and the like. The electron injection layer 1013e is configured, for example, of lithium fluoride (LiF) and the like. The connection layer 1013f is configured, for example, Alq3, HAT or the like which is doped with 5% Mg. The thicknesses of these layers included in the organic layer 1013 preferably are, for example, in ranges of 5 nm or more and 50 nm or less for the light emitting layer 1013a, 1 nm or more and 20 nm or less for the positive hole injection layer 1013b, 15 nm or more and 100 nm or less for the positive hole transport layer 1013c, and 15 nm or more and 200 nm or less for the electron transport layer 1013d and electron injection layer 1013e, respectively.

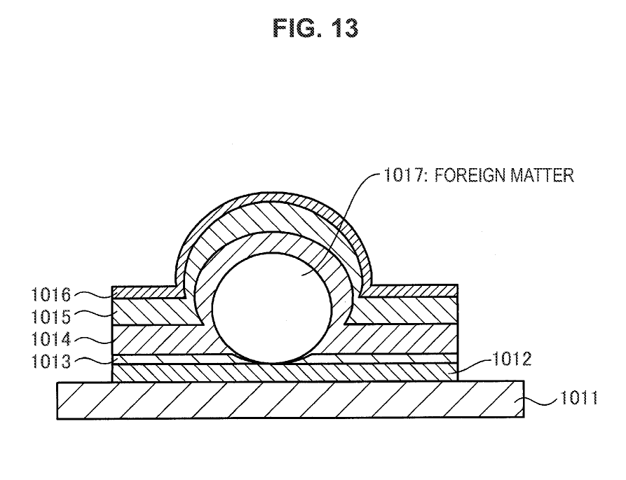

The first resistance layer 1014 is transparent with respect to light from the light emitting layer 1013a. The electric resistivity of a material included in the first resistance layer 1014 is selected, for example, being 1×10⁶ Ω·m or more and 1×10¹⁰ Ω·m or less (or 1×10⁴ Ω·cm or more and 1×10⁸ Ω·cm or less), or preferably, 1×10⁸ Ω·m or more and 1×10⁹ Ω·m or less (or 1×10⁶ Ω·cm or more and 1×10⁷ Ω·cm or less), whereas it is not limited to this. The thickness of the first resistance layer 1014 is selected, for example, being 0.1 μm or more and 1 μm or less, whereas it is not limited to this. A material included in the first resistance layer 1014 is selected appropriately, and preferably, oxide semiconductor is used for it. Specifically, examples of such oxide semiconductor can include, for example, niobium oxide (Nb₂O₅), titanium oxide (TiO₂), molybdenum oxide (MoO₂, MoO₃), tantalum oxide (Ta₂O₅), hafnium oxide (HfO), IGZO, a mixture of niobium oxide and titanium oxide, a mixture of titanium oxide and zinc oxide (ZnO), a mixture of silicon oxide (SiO₂) and tin oxide (SnO₂), a combination of two or more of these materials, and the like. The electric resistivity of the material included in the first resistance layer 1014 and the thickness of the first resistance layer 1014 are determined based on drive voltage of this organic EL element and coverage characteristics of this first resistance layer 1014. Namely, the electric resistivity of the material included in this first resistance layer 1014 and the thickness of the first resistance layer 1014 are selected specifically such that voltage drop at this first resistance layer 1014 in driving this organic EL element is 0.05V or more and 1.0 V or less, for example. Preferably, as illustrated in FIG. 13, the thickness of the first resistance layer 1014 is selected such that, in case, for example, of foreign matter 17 being on the first electrode 1012, the first resistance layer 1014 formed thereon completely cover the foreign matter 1017 and the second electrode 1016 formed at the last stage is not brought into contact with the first electrode 1012.

The second resistance layer 1015 is transparent with respect to light from the light emitting layer 1013a. The electric resistivity of a material included in the second resistance layer 1015 is selected, for example, being 1×10⁰ Ω·m or more and 1×10⁵ Ω·m or less (or 1×10⁻² Ω·cm or more and 1×10³ Ω·cm or less), whereas it is not limited to this. The thickness of the second resistance layer is selected, for example, being 0.5 μm or more, or preferably, 1 μm or more, whereas it is not limited to this. The maximum of the thickness of the second resistance layer 1015 is not restricted specifically, whereas the thickness of the second resistance layer 1015 is generally 5 μm or less, or typically, 2 μm or less. A material included in the second resistance layer 1015 is selected appropriately, and preferably, oxide semiconductor is used similarly to the material included in the first resistance layer 1014. Specifically, examples of such oxide semiconductor can include, for example, niobium oxide (Nb₂O₅), titanium oxide (TiO₂), molybdenum oxide (MoO₂, MoO₃), tantalum oxide (Ta₂O₅), hafnium oxide (HfO), IGZO, a mixture of niobium oxide and titanium oxide, a mixture of titanium oxide and zinc oxide (ZnO), a mixture of silicon oxide (SiO₂) and tin oxide (SnO₂), a combination of two or more of these materials, and the like. The material included in the second resistance layer 1015 may be same or different to or from the material composing the first resistance layer 1014, and is selected appropriately as wanted. Making the electric resistivity of the material included in the second resistance layer 1015 lower than the electric resistivity of the material included in the first resistance layer 1014 enables to increase the thickness of the second resistance layer 1015 without increasing the drive voltage of the organic EL element. When the material included in the second resistance layer 1015 is same as the material included in the first resistance layer 1014, the following way is, for example, used in order to making the electric resistivity of the material included in the second resistance layer 1015 lower than the electric resistivity of the material included in the first resistance layer 1014. Namely, the electric resistivities of these can be changed by adjusting the partial pressures of oxygen in an atmosphere used for film deposition in performing the film deposition of the first resistance layer 1014 and second resistance layer 1015, for example, in the sputtering method. Specifically, the partial pressure of oxygen in an atmosphere during the film deposition of the second resistance layer 1015 is made lower than the partial pressure of oxygen in an atmosphere during the film deposition of the first resistance layer 1014, and thereby, the electric resistivity of the material included in the second resistance layer 1015 can be made lower than the electric resistivity of the material included in the first resistance layer 1014. Thickening the second resistance layer 1015 enables to increase the distance between the first electrode 1012 and second electrode 1016, and thereby, to reduce the pitch of interference on light from the light emitting layer 1012a and the influence of the interference.

The second electrode 1016 is transparent with respect to light from the light emitting layer 1013a, and used for the cathodic electrode. Specifically, the second electrode 1016 is configured, for example, of indium tin oxide (ITO) or oxide of indium and zinc used for a typical transparent electrode material. Since the transparent electrode typically tends to have a light absorption property in a wavelength range equal to or smaller than 450 nm, forming this transparent electrode thick causes absorption of light emitted from the light emitting layer 1013a particularly in case of blue light emission, this resulting in reduced light emission efficiency. Therefore, the thinner if at all possible, specifically being 200 nm or less, for example, the more desirable.

### [Manufacturing Method of Organic EL Element]

This organic EL element can be fabricated, for example, as follows. First, the substrate 1011 is prepared.

Next, on this substrate 1011, a film of the above-mentioned electrode material is formed, for example, due to the sputtering method, vacuum deposition method or the like, affording the first electrode 1012.

Next, on this first electrode 1012, the organic layer 1013 is formed due to the vacuum deposition method, coating method or the like.

Next, on this organic layer 1013, a film of the above-mentioned resistance material is formed, for example, due to the sputtering method, vacuum deposition method, chemical vapor deposition (CVD) method, ion plating method or the like, affording the first resistance layer 1014.

Next, on this first resistance layer 1014, a film of the above-mentioned resistance material is formed, for example, due to the sputtering method, vacuum deposition method, CVD method, ion plating method or the like, affording the second resistance layer 1015. At this stage, the total thickness of the second resistance layer 1015 and first resistance layer 1014 is adjusted to be 1 μm or more. Thereby, as illustrated in FIG. 13, even when, for example, the foreign matter 1017 is on the first electrode 1012, the foreign matter 1017 is completely covered with these thick second resistance layer 1015 and first resistance layer 1014 having the total thickness of 1 μm or more. Therefore, the second electrode 1016 formed on the second resistance layer 1015 can be prevented from being brought into contact with the first electrode 1012.

Next, on this second resistance layer 1015, a film of the above-mentioned electrode material is formed, for example, due to the sputtering method, vacuum deposition method or the like, affording the second electrode 1016.

After that, the first electrode 1012, organic layer 1013, first resistance layer 1014, second resistance layer 1015 and second electrode 1016 undergo patterning into a predetermined shape due to the etching as wanted.

According to the above, the organic EL element illustrated in FIG. 11 as a target is fabricated.

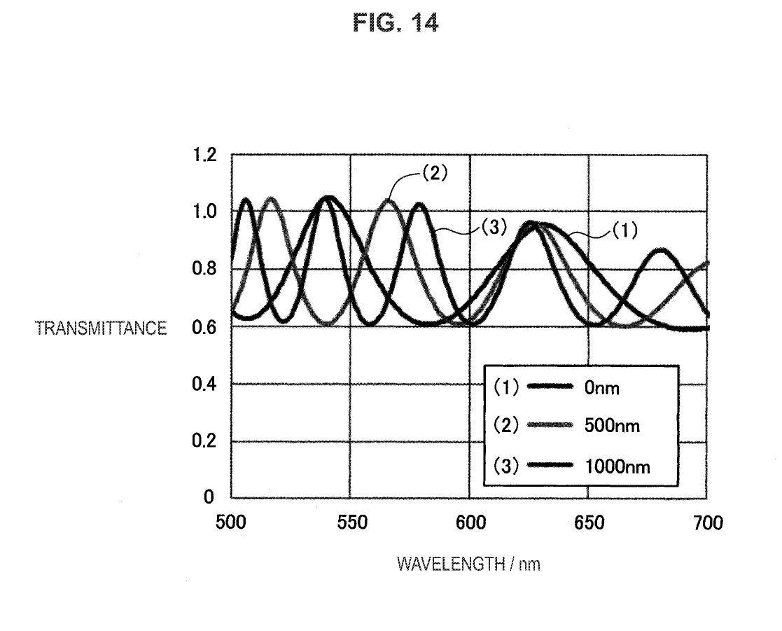

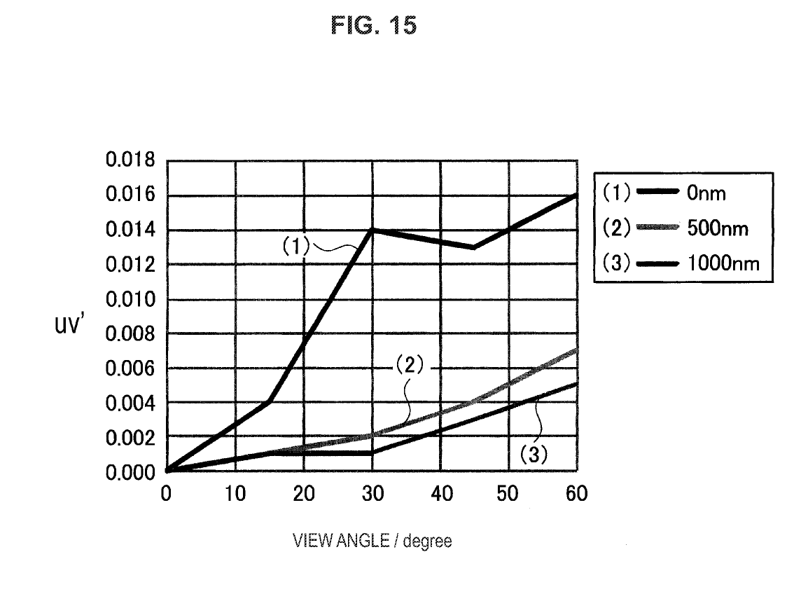

FIG. 14 illustrates change in transmission spectrum with respect to light from the light emitting layer 1013a according to change in thickness of the second resistance layer 1015, and FIG. 15 change in chromaticity view angle characteristics. Herein, the emitted light color of the light emitting layer 1013a is green, the thickness of the organic layer 1013 is 200 nm, the thickness of the first resistance layer 1014 is 500 nm, the thickness of the second resistance layer 1015 is any of 0 nm, 500 nm and 1000 nm, and the second electrode 1016 employs a transparent electrode with a thickness of 200 nm. FIG. 14 depicts that, as the thickness of the second resistance layer 1015 increases, the pitch of the interference is narrower. Along with this, FIG. 15 depicts that the chromaticity view angle characteristics are improved more. Moreover, reducing the influence of the interference by decreasing the thickness of the second resistance layer 1015 enables to reduce change in view angle with respect to distribution of thicknesses of the second resistance layer 1015.

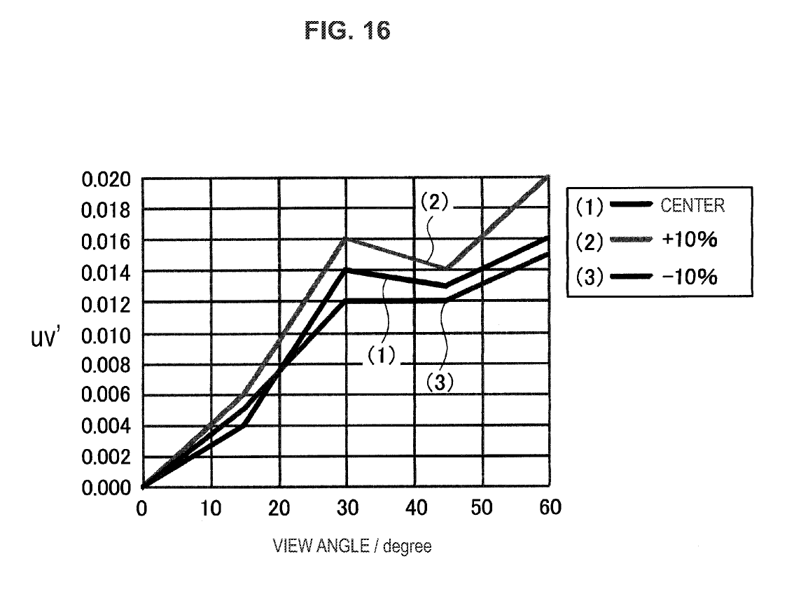

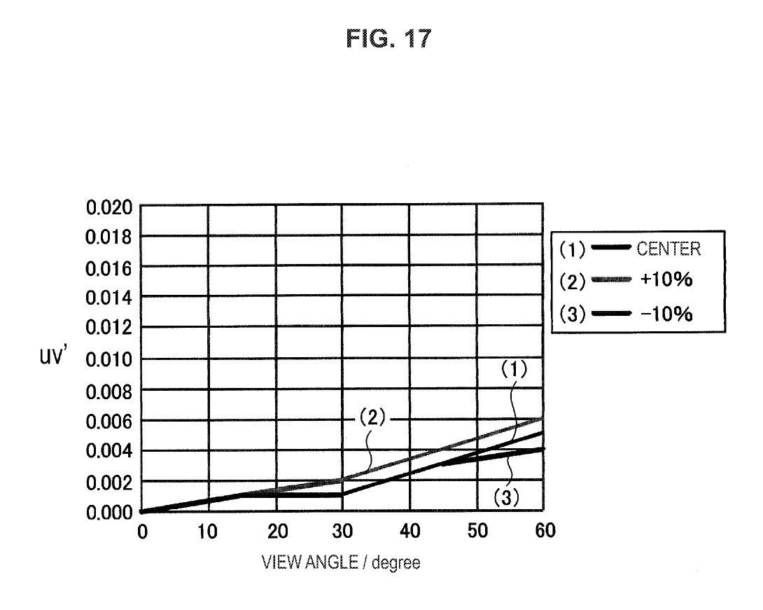

FIG. 16 illustrates change in chromaticity view angle characteristics according to change in total thickness of the first resistance layer 1014 and second resistance layer 1015 ranging ±10% relative to the thickness of the center when the thickness of the second resistance layer 1015 is 0 nm. Moreover, FIG. 17 illustrates change in chromaticity view angle characteristics according to change in total thickness of the first resistance layer 1014 and second resistance layer 1015 ranging ±10% relative to the thickness of the center when the thickness of the second resistance layer 1015 is 1000 nm. FIG. 16 and FIG. 17 depict attainment of excellent view angle characteristics even when the total thickness of the first resistance layer 1014 and second resistance layer 1015 changes ranging ±10%.

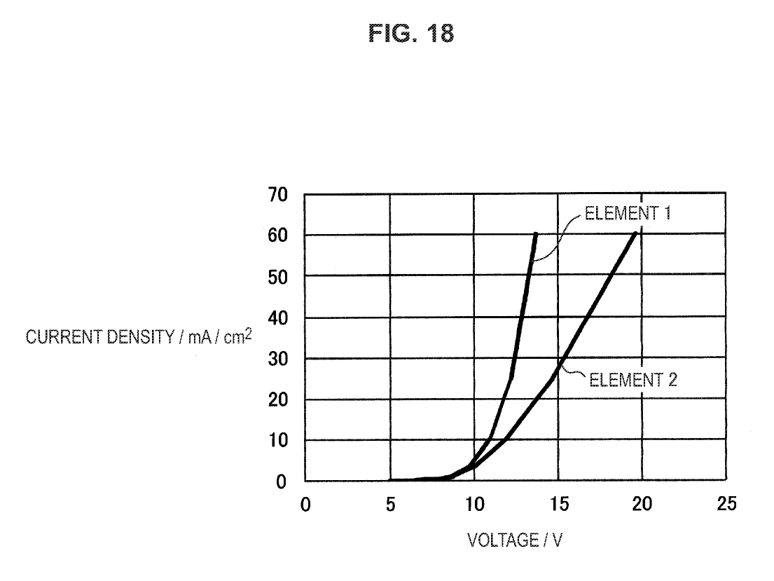

Even an increase of the total thickness of the first resistance layer 1014 and second resistance layer 1015 in order to improve the view angle characteristics can attain suppression of an increase of the drive voltage of the light emitting element since the electric resistivity of the material included in the second resistance layer 1015 is lower than the electric resistivity of the material included in the first resistance layer 1014. Detailed explanation is as follows. An organic EL element (element 1001) is fabricated, where the electric resistivity of the material included in the first resistance layer 1014 is 1×10⁶ Ω·cm, the thickness of the first resistance layer 1014 is 500 nm, the electric resistivity of the material included in the second resistance layer 1015 is 1×10³ Ω·cm, and the thickness of the second resistance layer 1015 is 1000 nm. An organic EL element (element 1002) is fabricated, where the electric resistivity of the material included in the first resistance layer 1014 is 1×10⁶ Ω·cm, the thickness of the first resistance layer 1014 is 1500 nm which equals to the total thickness of the first resistance layer 1014 and second resistance layer 1015 of the element 1001, and the second resistance layer 1015 is not provided. In this case, the element 1001 with 1500 nm of total thickness of the first resistance layer 1014 and second resistance layer 1015 has a less in-series resistance compared with the element 1002 which has 1500 nm of the first resistance layer 1014 and does not have the second resistance layer 1015. FIG. 18 illustrates measurements of voltage-current density characteristics of these elements 1001 and 1002. As illustrated in FIG. 18, the element can suppress the voltage increase more compared with the element 1002 as it has a less in-series resistance.

As above, according to SECOND EMBODIMENT, an organic EL element can be realized which is capable of preventing short circuits between the first electrode 1012 and second electrode 1016 even when the foreign matter 1017 or the like is on the first electrode 1012, and in addition, is excellent due to lowness in drive voltage and excellence in view angle characteristics. Moreover, change in view angle characteristics can be suppressed small even in change in total thickness of the first resistance layer 1014 and second resistance layer 1015, this attaining a wide margin for the total thickness of the first resistance layer 1014 and second resistance layer 1015. Therefore, yields and quality of organic EL elements can be improved.

### 3. Third Embodiment

### [Organic EL Element]

A bottom emission type organic EL element is presented. In this organic EL element, the substrate 1011 and first electrode 1012 of the organic EL element according to SECOND EMBODIMENT are transparent with respect to light from the light emitting layer 1013a and the second electrode 1016 reflects the light from the light emitting layer 1013a instead. Except these matters, this organic EL element is similar to the organic EL element according to SECOND EMBODIMENT.

### [Manufacturing Method of Organic EL Element]

A manufacturing method of this organic EL element is similar to the manufacturing method of the organic EL element according to SECOND EMBODIMENT.

THIRD EMBODIMENT as above can attain the advantages similar to SECOND EMBODIMENT.

### 4. Fourth Embodiment

### [Display Apparatus]

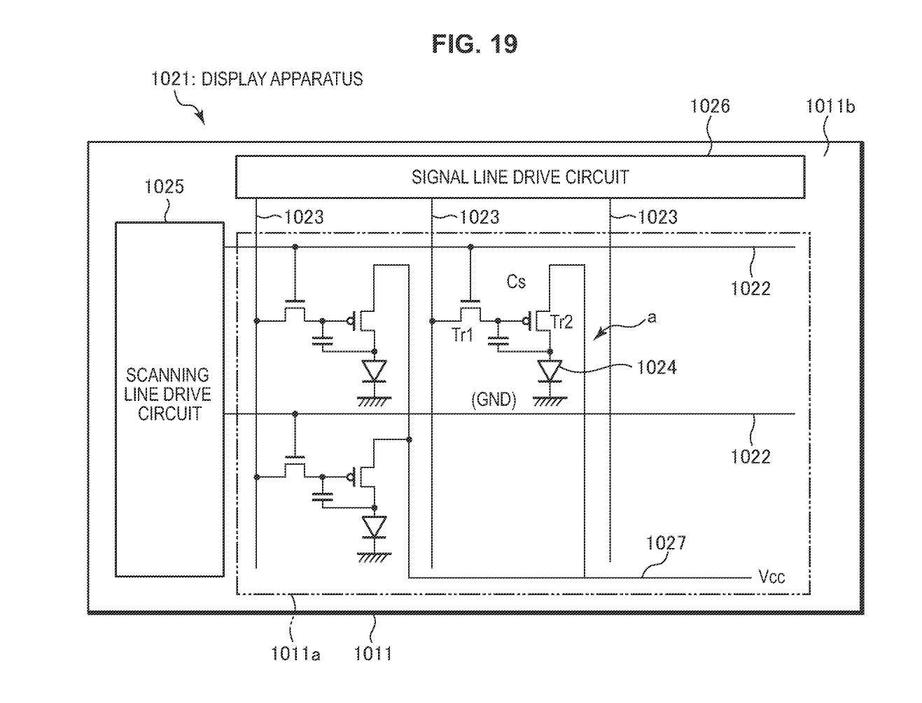

A display apparatus according to a fourth embodiment is an active matrix display apparatus in which the organic EL elements according to SECOND EMBODIMENT are formed and arranged on a substrate. FIG. 19 illustrates the whole configuration of this display apparatus 1021.

As illustrated in FIG. 19, a display region 1011a and a surrounding region 1011b thereof are provided on the substrate 1011 of the display apparatus 1021. The display region 1011a includes a plurality of scanning lines 1022 and a plurality of signal lines 1023, these disposed vertically and horizontally, and is configured as a pixel array section in which one pixel a is provided corresponding to each of intersections. In each pixel a, the organic EL element 1024 is provided. Moreover, the surrounding region 1011b includes a scanning line drive circuit 1025 scanning and driving the scanning line 1022, and a signal line drive circuit 1026 supplying a picture signal (that is, an input signal) corresponding to luminance information to the signal line 1023, these disposed in it.

The pixel circuit provided in each pixel a includes, for example, the organic EL element 1024, a drive transistor Tr1001, a write transistor (sampling transistor) Tr1002, and a retention capacity Cs. Furthermore, the picture signal written from the signal line 1023 through the write transistor Tr1002 is held in the retention capacity Cs by drive of the scanning line drive circuit 1025, and a current corresponding to the held signal amount is supplied to the organic EL element 1024. The organic EL element 1024 emits light at a luminance corresponding to this current value. In addition, the thin film transistor Tr1002 for driving and the retention capacity Cs are connected to a common power supply line (Vcc) 1027.

In addition, the structure of the pixel circuit mentioned above is just one example. If expected, the pixel circuit may be configured by providing a capacitance element, and further, providing a plurality of transistors in the pixel circuit. Moreover, an expected drive circuit is added to the surrounding region 1011b according to changes of the pixel circuit.

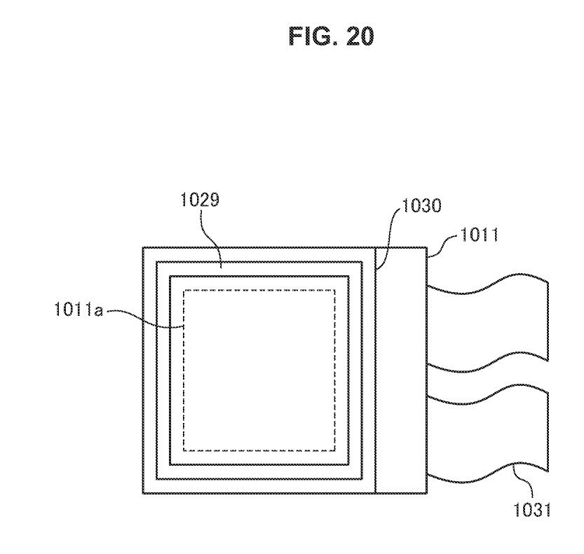

In addition, this display apparatus 1021 includes one having a module shape with a sealed structure as illustrated in FIG. 20. For example, a display module in which a sealing section 1029 is provided so as to surround the display region 1011a as a pixel array section and which is bonded to a facing section (a sealing substrate 1030) such as transparent glass by the sealing section 1029 as an adhesive corresponds to the example. A color filter, a protective film, a light shielding film and the like may be provided in the transparent sealing substrate 1030. In addition, a flexible print board 1031 for inputting/outputting a signal and the like from outside to the display region 1011a (the pixel array section) may be provided in the substrate 1011 as the display module in which the display region 1011a is formed.

The above-mentioned organic EL element 1024 and display apparatus 1021 can prevent short circuits between the first electrode 1012 and second electrode 1016 caused by the presence of the foreign matter 1017 or the like on the first electrode 1012 and attain excellent chromaticity view angle characteristics.

In addition, the organic EL element 1024 is not limited to usage for the active matrix display apparatus 1021 utilizing a TFT substrate, but can be applied to an organic EL element used for a passive display apparatus, affording the similar effects. In case of a passive display apparatus, one of the first electrode 1012 and second electrode 1016 is configured as a signal line and the other is configured as a scanning line.

FOURTH EMBODIMENT describes a top emission type organic EL element 1024 in which emitted light is taken from the second electrode 1016 side provided on the opposite side to the substrate 1011, whereas the bottom emission type organic EL element according to THIRD EMBODIMENT in which emitted light is taken from the substrate 1011 side may be used as an organic EL element 1024. In this case, in the layered structure described with reference to FIG. 11, the first electrode 1012 on the substrate 1011 which electrode is made of a transparent material is configured of a transparent electrode material large in work function such, for example, as ITO instead. Thereby, emitted light is taken from both of the substrate 1011 side and the opposite side to the substrate 1011. Moreover, emitted light is taken only from the substrate 1011 side by configuring the second electrode 1016 of a reflective material in such a configuration instead. In this case, the uppermost portion of the second electrode 1016 may include a sealing electrode made of AuGe, Au or Pt.

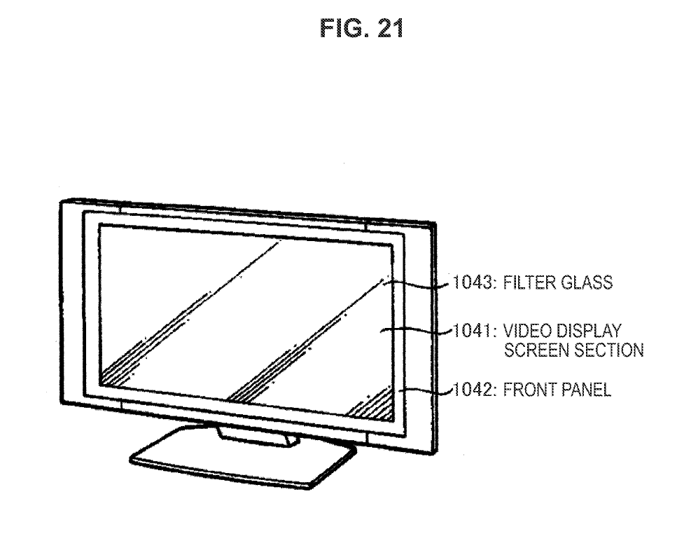

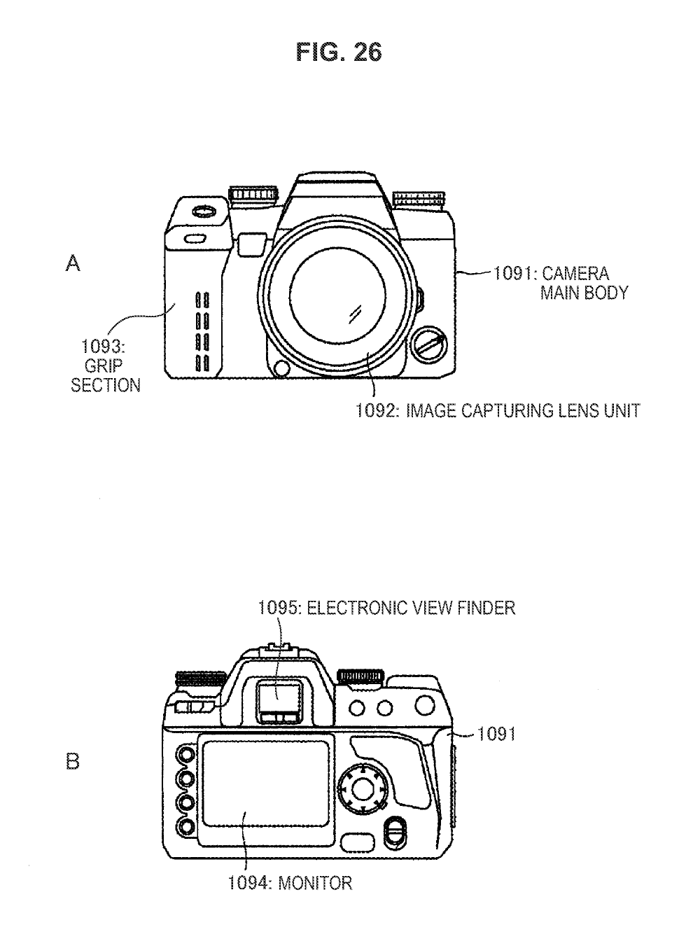

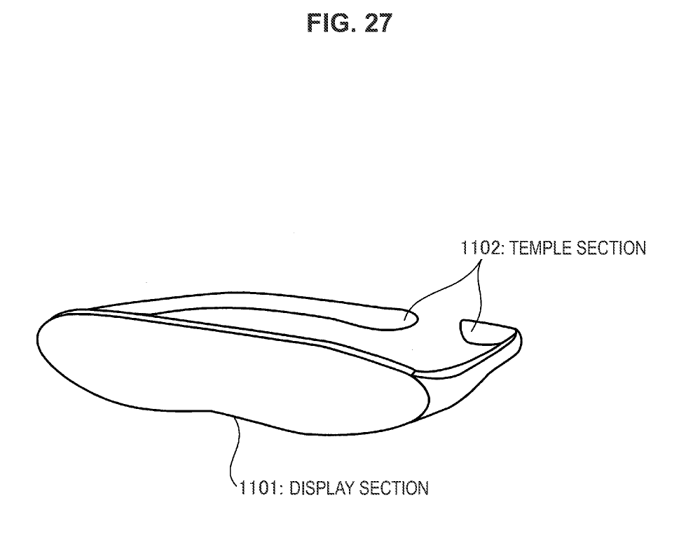

Moreover, the above-mentioned display apparatus according to the embodiment is applicable to display apparatuses in electronic equipment in various fields for displaying a picture signal inputted to the electronic equipment or a picture signal generated inside the electronic equipment as an image or a picture, such as various kinds of electronic equipment illustrated in FIGS. 21 to 25 such, for example, as a digital camera, a notebook personal computer, a portable terminal device such as a portable phone, and a video camera. Furthermore, the organic EL element 1024 can be driven at low voltage and enhances light extraction efficiency to the front, and thus, is quite effective and suitable for applications, for example, especially to an electronic view finder in a digital single-lens reflex camera illustrated in FIG. 26, a head mounted display illustrated in FIG. 27, and the like, in which applications low drive voltage is expected and the view angle to the display is limited. Hereafter, examples of electronic equipment to which this display apparatus is applied are described.

FIG. 21 is a perspective view of a television device to which this display apparatus is applied. The television device according to the examples of application includes a video display screen section 1041 including a front panel 1042, a filter glass 1043 and the like, and is fabricated by using this display apparatus as the video display screen section 1041.

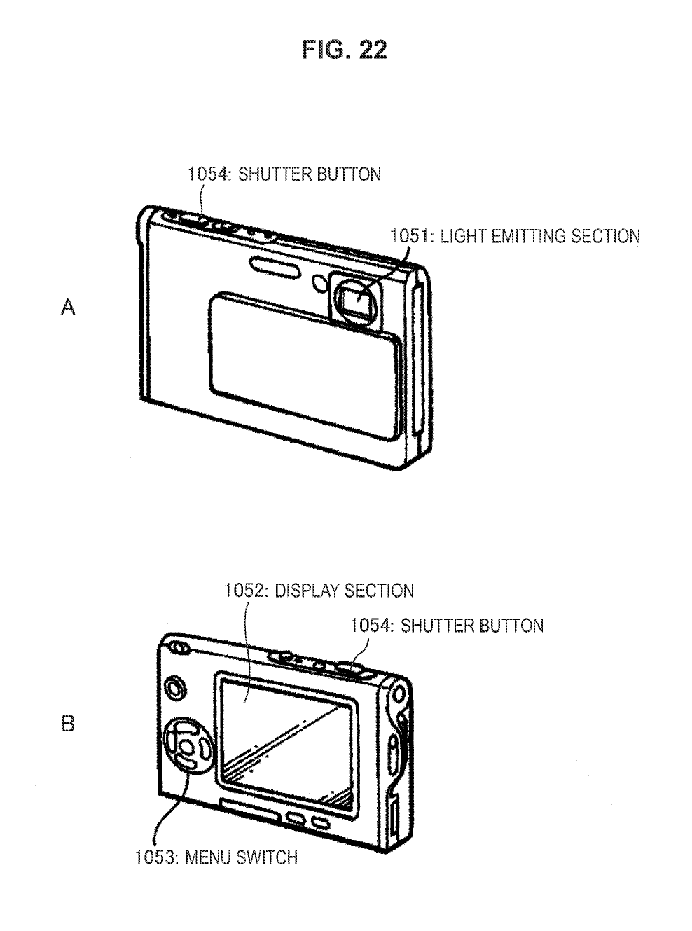

FIG. 22 is a diagram illustrating a digital camera to which this display apparatus is applied, and FIG. 22A is a perspective view as seen from a front side and FIG. 22B is a perspective view as seen from a rear side. The digital camera according to the application example includes a light emitting section 1051 for a flash, a display section 1052, a menu switch 1053, a shutter button 1054 and the like, and is fabricated by using this display apparatus as the display section 1052.

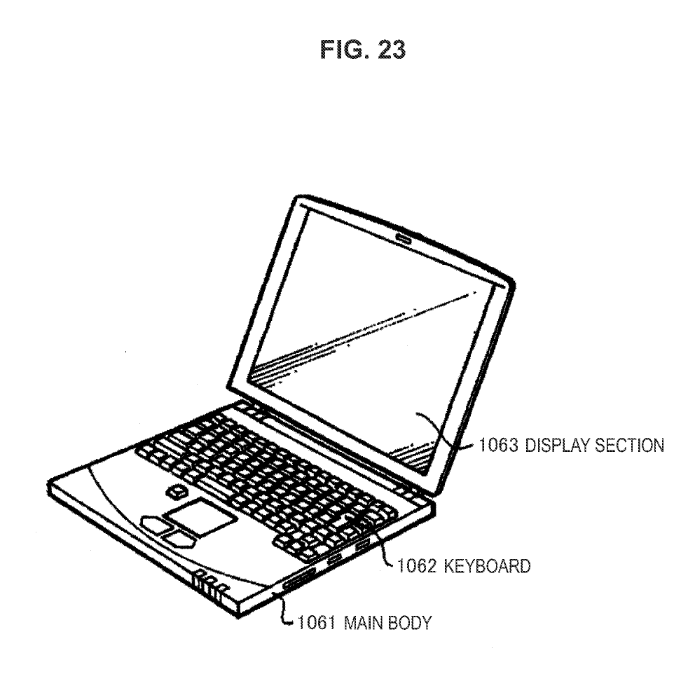

FIG. 23 is a perspective view illustrating a notebook personal computer to which this display apparatus is applied. The notebook personal computer according to the application example includes a main body 1061, a keyboard 1062 for operation of inputting characters and the like, a display section 1063 for displaying an image, and the like, and is fabricated by using this display apparatus as the display section 1063.

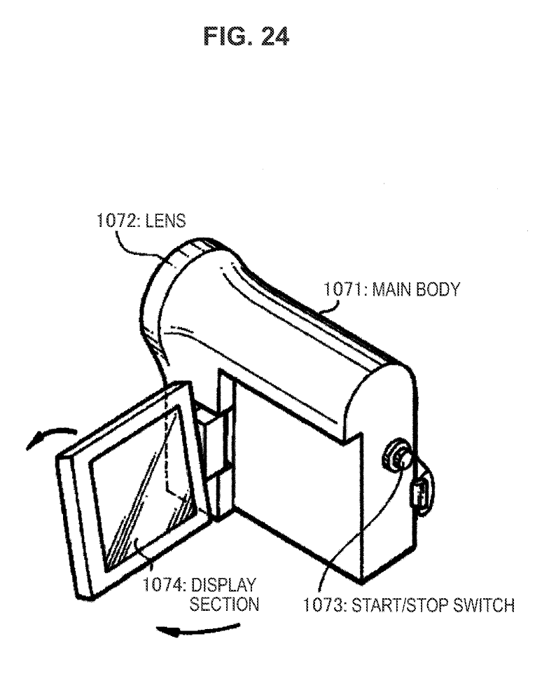

FIG. 24 is a perspective view illustrating a video camera to which this display apparatus is applied. The video camera according to the application example includes a main body 1071, a lens 1072 for capturing an image of the subject provided on the front side face thereof, a start/stop switch 1073 in capturing an image, a display section 1074, and the like, and is fabricated by using this display apparatus as the display section 1074.

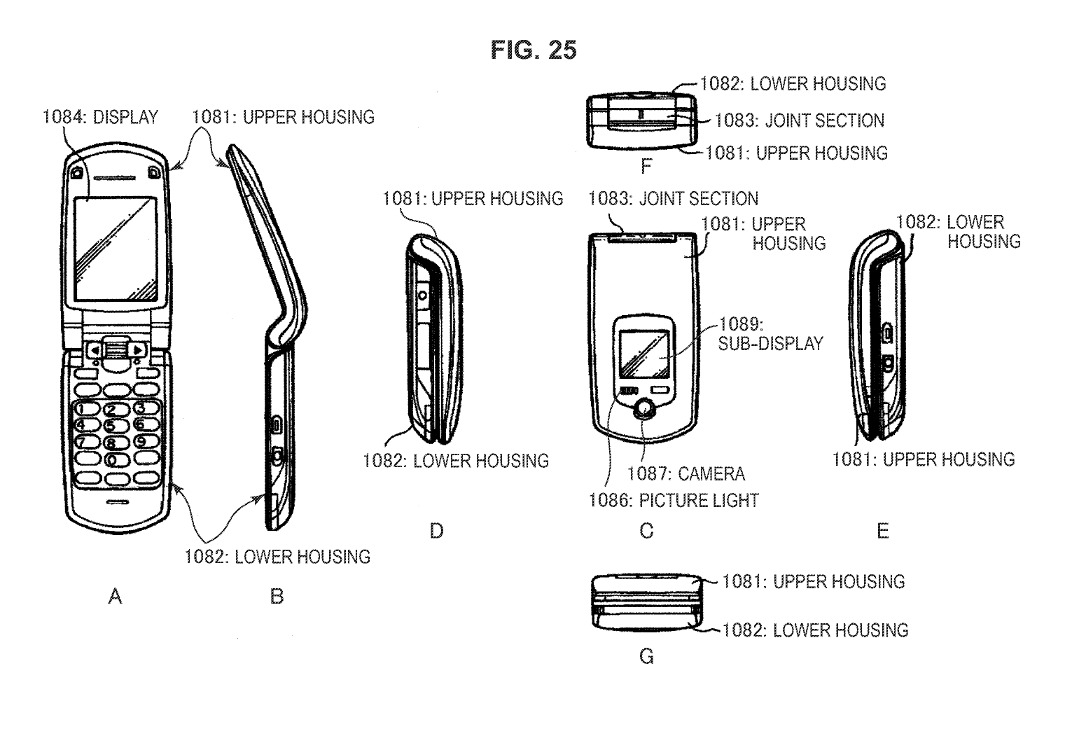

FIG. 25 is a diagram illustrating a portable terminal apparatus, for example, a portable phone to which this display apparatus is applied, and FIG. 25A is an elevation view in an unclosed state, FIG. 25B is a lateral view thereof, FIG. 25C is an elevation view in a closed state, FIG. 25D is a left side view, FIG. 25E is a right side view, FIG. 25F is a top view, and FIG. 25G is a bottom view. The portable phone according to the application example includes an upper housing 1081 and a lower housing 1082, a joint section (herein, a hinge section) 1083, a display 1084, a picture light 1086, a camera 1087, a sub-display 1089, and the like, and is fabricated by using this display apparatus as the display 1084 and the sub-display 1089.

FIG. 26 illustrates a digital single-lens reflex camera to which this display apparatus is applied, and FIG. 26A is an elevation view, and FIG. 26B is a rear view. The digital single-lens reflex camera includes a camera main body 1091, an image capturing lens unit 1092, a grip section 1093, a monitor 1094, an electronic view finder 1095 and the like, and is fabricated by using this display apparatus as the electronic view finder 1095.

FIG. 27 is a perspective view illustrating a head mounted display to which the display apparatus is applied. The head mounted display includes a display section 1101, a temple section 1102 and the like, and is fabricated by using this display apparatus as the display section 1101.

### 5. Fifth Embodiment

### [Lighting Apparatus]

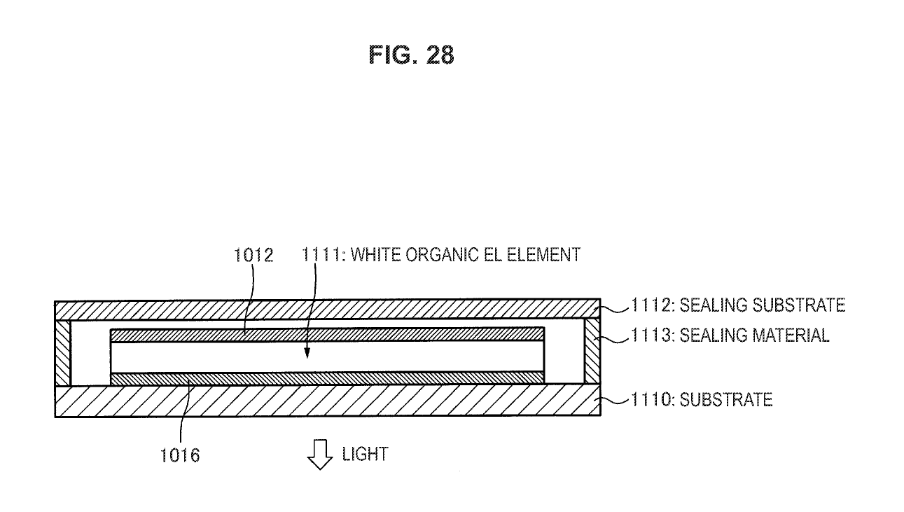

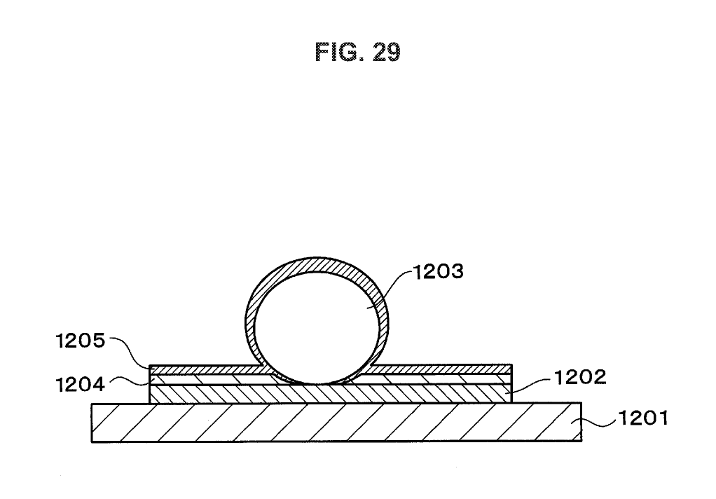

FIG. 28 illustrates a lighting apparatus according to a fifth embodiment. As illustrated in FIG. 28, the lighting apparatus includes a transparent substrate 1110, and a white organic EL element 1111 according to SECOND EMBODIMENT provided thereon. In this case, the white organic EL element 1111 is disposed on the substrate 1110, facing the second electrode 1016 side downward. Therefore, light emitted from the second electrode 1016 side is taken outside, passing through the substrate 1110. A sealing substrate 1112 is provided facing the substrate 1110, these interposing the white organic EL element 1111. A sealing material 1113 seals the periphery of the sealing substrate 1112 and substrate 1110. A planar shape of this lighting apparatus is selected as wanted and is, for example, a square or a rectangle. FIG. 28 illustrates only one white organic EL element 1111, whereas a plurality of white organic EL elements 1111 may be disposed in a desired arrangement on the substrate 1110. This lighting apparatus is similar to known organic EL lighting apparatuses except regarding the detailed configuration of the white organic EL element 1111 and the above-mentioned configuration.

According to FIFTH EMBODIMENT, use of the white organic EL element 1111 according to SECOND EMBODIMENT enables to realize a lighting apparatus which is less in angle dependency, excellent in light distribution characteristics, and low in power consumption and costs.

It should be understood by those skilled in the art that various modifications, combinations, sub-combinations and alterations may occur depending on design requirements and other factors insofar as they are within the scope of the appended claims or the equivalents thereof

For example, the values, structures, configurations, shapes, materials and the like presented in the above-mentioned embodiments are simply examples, and values, structures, configurations, shapes, materials and the like different from these may be used as wanted.

Additionally, the present technology may also be configured as below.

(1) A light emitting element including:

a first electrode;

an organic layer including a light emitting layer of an organic light emitting material, on the first electrode;

a first resistance layer on the organic layer;

a second resistance layer including a material lower in electric resistivity than a material included in the first resistance layer, on the first resistance layer; and

a second electrode on the second resistance layer,

wherein one of the first electrode and the second electrode reflects light from the light emitting layer and the other of the first electrode and the second electrode transmits the light from the light emitting layer, and

wherein a total thickness of the first resistance layer and the second resistance layer is 1 μm or more.

(2) The light emitting element according to (1),

wherein electric resistivity of the material included in the first resistance layer is 1×10⁶ Ω·m or more and 1×10¹⁰ Ω·m, and wherein a thickness of the first resistance layer is 0.1 μm or more and 1 μm or less.

(3) The light emitting element according to (1) or (2),

wherein electric resistivity of a material included in the second resistance layer is 1×10⁰ Ω·m or more and 1×10⁵ Ω·m, and

wherein a thickness of the second resistance layer is 0.5 μm or more.

(4) The light emitting element according to any one of (1) to (3),

wherein the first resistance layer and the second resistance layer are made of oxide semiconductor.

(5) The light emitting element according to any one of (1) to (4),

wherein the first electrode is provided on a substrate.

(6) The light emitting element according to (5),

wherein the first electrode reflects the light from the light emitting layer, and

wherein the first resistance layer, the second resistance layer and the second electrode transmit the light from the light emitting layer.

(7) The light emitting element according to (5),

wherein the first electrode, the first resistance layer and the second resistance layer transmit the light from the light emitting layer, and

wherein the second electrode reflects the light from the light emitting layer.

The present disclosure contains subject matters related to those disclosed in Japanese Priority Patent Application JP 2012-072825 filed in the Japan Patent Office on Mar. 28, 2012, and Japanese Priority Patent Application JP 2012-076212 filed in the Japan Patent Office on Mar. 29, 2012, the entire content of which is hereby incorporated by reference.

What is claimed is:

1. A light emitting element comprising:
a first electrode;
an organic layer having a light emitting layer, formed on the first electrode;
a charge generation layer formed on the organic layer;
a resistance layer formed on the charge generation layer; and
a second electrode formed on the resistance layer,
wherein the first electrode reflects light emitted from the light emitting layer and the second electrode transmits the light emitted from the light emitting layer, and
wherein the charge generation layer includes a layered structure of, sequentially in order from the organic layer, a mixing layer containing a chelate material, and an alkali earth metal element or an alkali metal element, and an acceptor layer containing an acceptor material.

2. The light emitting element according to claim 1,
wherein electric resistivity of a material included in the resistance layer is 1×10² Ω·cm to 1×10⁶ Ω·cm, and
wherein a thickness of the resistance layer over the organic layer is 0.1 μm to 2 μm.

3. The light emitting element according to claim 2,
wherein the acceptor layer at least contains a compound represented by chemical formula 1 below: 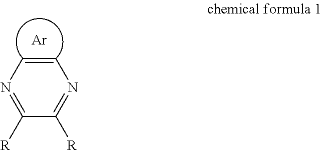
where, in chemical formula 1 above, Ar represents an aryl group and R represents a hydrogen atom, an alkyl group having 1 to 10 carbon atoms, an alkyloxy group having 1 to 10 carbon atoms, a dialkylamine group having 1 to 10 carbon atoms, a halogen element, a cyano group, or a substituted or unsubstituted silyl group.

4. The light emitting element according to claim 3,
wherein the chelate material at least contains a phenanthroline derivative containing at least one phenanthroline ring represented by chemical formula 2 below:

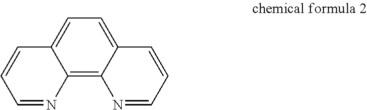 [SMILES: c1cnc2c(c1)ccc1cccnc12]

5. The light emitting element according to claim 4,
wherein the mixing layer contains the chelate material, and one of Li and Cs.

6. The light emitting element according to claim 5,
wherein a molar ratio of a mixture of the chelate material, and the alkali earth metal element or the alkali metal element is 1:5 to 2:1 in the mixing layer.

7. A display apparatus comprising:
a light emitting element including
a first electrode,
an organic layer having a light emitting layer, formed on the first electrode,
a charge generation layer formed on the organic layer,
a resistance layer formed on the charge generation layer, and
a second electrode formed on the resistance layer,
wherein the first electrode reflects light emitted from the light emitting layer and the second electrode transmits the light emitted from the light emitting layer, and
wherein the charge generation layer includes a layered structure of, sequentially in order from the organic layer, of a mixing layer containing a chelate material, and an alkali earth metal element or an alkali metal element, and an acceptor layer containing an acceptor material.

8. A light emitting element comprising:
a first electrode;
an organic layer including a light emitting layer of an organic light emitting material, on the first electrode;
a first resistance layer on the organic layer;
a second resistance layer including a material lower in electric resistivity than a material included in the first resistance layer, on the first resistance layer; and
a second electrode on the second resistance layer,
wherein one of the first electrode and the second electrode reflects light from the light emitting layer and the other of the first electrode and the second electrode transmits the light from the light emitting layer, and
wherein a total thickness of the first resistance layer and the second resistance layer is 1 μm or more.

9. The light emitting element according to claim 8,
wherein electric resistivity of the material included in the first resistance layer is 1×10⁶ Ω·m or more and 1×10¹⁰ Ω·m, and
wherein a thickness of the first resistance layer is 0.1 μm or more and 1 μm or less.

10. The light emitting element according to claim 9,
wherein electric resistivity of a material included in the second resistance layer is 1×10⁰ Ω·m or more and 1×10⁵ Ω·m, and
wherein a thickness of the second resistance layer is 0.5 μm or more.

11. The light emitting element according to claim 10,
wherein the first resistance layer and the second resistance layer are made of oxide semiconductor.

12. The light emitting element according to claim 11,
wherein the first electrode is provided on a substrate.

13. The light emitting element according to claim 12,
wherein the first electrode reflects the light from the light emitting layer, and
wherein the first resistance layer, the second resistance layer and the second electrode transmit the light from the light emitting layer.

14. The light emitting element according to claim 12,
wherein the first electrode, the first resistance layer and the second resistance layer transmit the light from the light emitting layer, and
wherein the second electrode reflects the light from the light emitting layer.

15. A method for manufacturing a light emitting element, the method comprising:
forming a first electrode on a substrate;
forming an organic layer including a light emitting layer of an organic light emitting material, on the first electrode;
sequentially forming, on the organic layer, a first resistance layer and a second resistance layer of a material lower in electric resistivity than a material included in the first resistance layer; and
forming a second electrode on the second resistance layer,
wherein one of the first electrode and the second electrode reflects light from the light emitting layer and the other of the first electrode and the second electrode transmits the light from the light emitting layer, and
wherein a total thickness of the first resistance layer and the second resistance layer is 1 μm or more.

16. A display apparatus comprising:
at least one light emitting element including
a first electrode,
an organic layer including a light emitting layer of an organic light emitting material, on the first electrode,
a first resistance layer on the organic layer,
a second resistance layer of a material lower in electric resistivity than a material included in the first resistance layer, on the first resistance layer, and
a second electrode on the second resistance layer,
wherein one of the first electrode and the second electrode reflects light from the light emitting layer and the other of the first electrode and the second electrode transmits the light from the light emitting layer, and
wherein a total thickness of the first resistance layer and the second resistance layer is 1 μm or more.

17. The display apparatus according to claim 16, comprising:
a drive substrate provided with an active element for supplying a display signal corresponding on a per-display-pixel basis to the light emitting element; and
a sealing substrate provided in a manner opposing to the drive substrate,
wherein the light emitting element is disposed between the drive substrate and the sealing substrate.

18. The display apparatus according to claim 17,
wherein a color filter transmitting the light radiated from the second electrode is provided in the substrate of the second electrode of the light emitting element out of the drive substrate and the sealing substrate.

19. A lighting apparatus comprising:
at least one light emitting element including
a first electrode,
an organic layer including a light emitting layer of an organic light emitting material, on the first electrode,
a first resistance layer on the organic layer,
a second resistance layer of a material lower in electric resistivity than a material included in the first resistance layer, on the first resistance layer, and
a second electrode on the second resistance layer,
wherein one of the first electrode and the second electrode reflects light from the light emitting layer and the other of the first electrode and the second electrode transmits the light from the light emitting layer, and
wherein a total thickness of the first resistance layer and the second resistance layer is 1 μm or more.
